(19) United States
(12) Patent Application Publication
(10) Pub. No.: US 2023/0421977 A1
(43) Pub. Date: Dec. 28, 2023

(54) System and method for generation and evolution of coupled hybrid acoustic media

(71) Applicant: Jake Araujo-Simon, Brooklyn, NY (US)

(72) Inventor: Jake Araujo-Simon, Brooklyn, NY (US)

(21) Appl. No.: 17/803,852

(22) Filed: Sep. 7, 2023

Related U.S. Application Data
(63) Continuation-in-part of application No. 16/290,461, filed on Mar. 1, 2019, now abandoned.
(60) Provisional application No. 62/795,841, filed on Jan. 23, 2019.
(60) Provisional application No. 62/637,089, filed on Mar. 1, 2018.

(51) Int. Cl. H04S 7/00; G06F 30/20

(52) U.S. Cl. CPC H04S 7/30; G06F 30/20; H04S 2400/15

(57) ABSTRACT

A cyber-physical system for the synchronous simulation of networks of acoustic media is described herein. An acoustic medium, which may be a composition of cyber and real world (i.e., physical) spaces is modeled as one or many coupled oscillating manifolds (OMs), i.e. sound pressure fields (SPF) defined over manifolds and evolving according to an inhomogeneous acoustic wave equation (IWE). Each manifold is approximated as a simplicial manifold, and the SPF data is evolved using a cotangent approximation to the continuous Laplace-Beltrami operator. The simplices of the manifold evolve concurrently with the SPF using an adaptive finite element method (AFEM) in a feedback loop such that simplices are concentrated where more energy is present in the sound field. Time evolution of the SPF is computed numerically. The computation is parallelizable over a plurality of computational platforms (CPs) which communicate in order to share pressure data over submanifold regions at which the OM are coupled.

Individual OMs in the network may differ in their topology and geometry, as well as in parameters, such as their respective speed of sound, that affect their dynamics. Interaction between acoustic media is modeled as directed sound transfer between OMs using harmonic mapping to map between submanifolds at the interface of the coupled OMs for localized forcing at the interface. The map may be chosen to be harmonic or conformal in order to minimize distortion due to reparameterization of the SPFs. OMs in the network of coupled oscillating manifolds (COMs) modeling a plurality of acoustic media are constrained to evolve synchronously using a safe-to-process protocol, and deterministic evolution of the entire network is ensured.

### RELATED APPLICATIONS

The present application is a continuation-in-part of non-provisional patent application Ser. No. 16/290,461 filed Mar. 1, 2019 by the same inventor, which in turn claims priority to provisional patent application Ser. No. 62/795,841 filed Jan. 23, 2019 by the same inventor and provisional patent application Ser. No. 62/637,089 filed Mar. 1 2018 by the same inventor.

### FIELD OF THE INVENTION

The present application is related to sound processing systems.

### BACKGROUND

Sound in the physical world propagates through acoustic media of various shapes, sizes, and material properties. It is also transferred between media when they are in contact via an interface, such as a gas-liquid or gas-solid interface. Interacting acoustic media in the real world evolve synchronously, in the sense that their responses to pressure fluctuations are effectively simultaneous and instantaneous. Interacting acoustic media also evolve deterministically, in that interactions are causally related to responses by the media at subsequent times. These properties of synchrony and determinism are essential for participants, such as speakers and musicians, to interact reliably. Physical acoustic media furthermore may have time-varying structure: for instance, they may be split or joined, such as when a door which is closed, separating a space into two rooms each filled with air, or when a door between two rooms is opened whereupon the parcels of air merge. In another example, the space in a theatre may be frequently repartitioned or reconfigured, such as from one play to the next. Thus, basic parameters of real-world acoustic media, such as shapes and sizes, may be time-varying and in flux. In order to handle common real-world situations, it is necessary to model pluralities of acoustic media that are heterogeneous, interconnected, coevolving, and time-varying geometrically and in their material coefficient.

Current systems and methods for simulating acoustic wave propagation focus on isolated spaces. Generally, current computational schemes for modeling sound propagation are either geometric or wave-based techniques. Geometric techniques such as image source and ray-tracing based methods are based on the assumption that sound travels as a ray and wavelength-dependent factors are usually neglected. Ray-tracing methods are computationally efficient compared to wave-based techniques, but typically do not well model acoustic phenomena such as diffraction. They are furthermore not suitable for the real-time simulation of large, time-varying environments, since they involve substantial precomputation. Wave-based methods, in contrast, directly solve the differential equations associated with an acoustic space of interest, and so inherently capture all acoustic effects. However, they in general require discretizing the acoustic media, and thus suffer from the curse of dimensionality since the number of discrete elements grows quickly in two or more dimensions as the size of the space and the maximum frequency of the simulation increases.

Thus, wave-based methods have traditionally been limited to simulation of low-frequency phenomena, or to non-real-time applications, due to their computational cost. But a real-world acoustic space will generally not be of a geometry for which an analytic solution to the acoustic wave equation of the entire space is a priori available. (However, if they are available, as in the cases of spherical, semi-circular, or cuboidal spaces, then specialized techniques such as Ambisonics and Wave Field Synthesis (WFS) can be effectively applied; see [S. Spors and J. Ahrens, “A Comparison of Wave Field Synthesis and Higher-Order Ambisonics with Respect to Physical Properties and Spatial Sampling”, presented at the 125th Audio Engineering Society Convention, 2008] for an overview of Ambisonics and WFS.) Thus, a general purpose wave-based method that minimizes the number of discrete elements required to represent acoustic space, and so avoids the curse of dimensionality, would be of interest, as it would overcome the reliance on analytic methods.

In US Patent Publication No. US 2016/0171131 by Morales et al., parallelization is used in conjunction with adaptive domain decomposition methods to speedup wave-based acoustic simulations. Computation of acoustic wave propagation is ammenable to parallelization because the Laplacian operator, which drives acoustic wave propagation, is inherently local. Therefore, solutions can be computed locally by splitting a larger environment into smaller regions, solving the wave equation within each of the regions separately subject to condition that the solutions be consistent over areas where the regions meet, and then recombining the local solutions. This may allow for high-frequency phenomena to be simulated in real-time for large acoustic environments. However, the wave-based method of Morales is limited to the simulation of standalone, homogeneous acoustic media (i.e., single, isolated acoustic spaces with a spatially-invariant speed of sound), and does not address the case of pluralities of interacting acoustic media. Morales furthermore relies on a so-called Adaptive Rectangular Decomposition (ARD) method, which decomposes a larger domain into smaller rectangular (cuboidal) pieces in order to make use of analytic solutions available for the wave equation in a rectilinear domain. Thus, Morales is only applicable to acoustic domains which are locally rectilinear in shape, and is reliant on closed-form solutions of the corresponding acoustic wave equations. Furthermore, Morale's ARD-based methods function by splitting the computation into a preprocessing stage and a simulation stage, partitioning the space into a plurality of partitions at the beginning of the process, and then performing simulations using a fixed, static model of the partitioned acoustic space. This does not allow for the possibility that the modeled acoustic space may have a time-varying structure. Furthermore, Morales's domain decomposition is based on geometric and topological features of the space, and not on the distribution of energy in the sound pressure field within the space.

It should also be noted that current systems and methods such as Morales are focused on the simulation of acoustic spaces on a computer, rather than on an integrated cyber-physical approach. Furthermore, it should be noted that modern computational platforms are increasingly distributed in nature, and capable of processing in different physical environments concurrently. Such systems require, however, that care be taken regarding time synchronization and the ordering of discrete events in the distributed system, or else important properties such as determinism are sacrificed. While deterministic programming models for distributed cyber-physical systems are still rare, essential components such as clock synchronization protocols are becoming more commonplace. For example, the IEEE 1588 standard defines a Precision Time Protocol (PTP) capable of delivering real-time clock precision at the order of nanoseconds on a local area network (LAN). The related IEEE 802.1AS standard is a variant of PTP designed for audio-visual bridging (AVB) and timing-sensitive networking (TSN), which form a suite of technical standards that serve as a foundation for determinstic networking in distributed networks and cyber-physical systems. The Meyer Sound CAL (column array loudspeaker) is one example of a system that uses AVB/TSN over an Ethernet LAN in order to coordinate the actions of many loudspeakers for the purpose of acoustic beamforming. However, such systems for control of sensors and actuators do not coordinate the concurrent computation of the evolution of a sound field in an acoustic space. Thus far, no system has married the use of deterministic CPS modelling with the real-time computation of acoustic wave propagation using a general mathematical model of acoustic space. Therefore, the present invention provides a temporally-integrated distributed embedded system and method for the evolution and/or generation of acoustic media that may be a hybrid of cyber and/or physical processes and componentry, wherein computational platforms containing sensors, actuators, and processors are embedded in different physical environments and communicate over a network, in order to distribute computation and synchronously process the evolution of a sound field.

### BRIEF DESCRIPTION OF THE DRAWINGS

FIG. 1 shows a pair of coupled oscillating manifolds (COMs), one disk-shaped and the other spherical, coupled over a disk-shaped region.

FIG. 2 shows a sequence of simplices and face relations between them.

FIG. 3 shows the construction of the star of a vertex in a simplicial manifold.

FIG. 4 shows the construction of the closure of the star of a vertex in a simplicial manifold.

FIG. 5 shows the construction of the link of a vertex in a simplicial manifold.

FIG. 6 shows the constructions of the boundary and interior of a collection of simplices which is a simplicial submanifold.

FIG. 7 shows a simplicial manifold, wherein the links of two vertices are shown in red, each of which is a simplicial 1-sphere (or circle).

FIG. 8 shows a tetrahedron (3-simplex) along with the adjacency matrices that encode the face relations of its vertices and edges and its edges and triangles.

FIG. 9 shows an interior angle βᵢ^{kl} at a vertex vᵢ in a simplicial manifold, and angles αᵢⱼ and βᵢⱼ that are opposite an edge in the same manifold.

FIG. 10 shows the velocity field associated with an underlying simplicial surface, including the height of the field at a vertex v.

FIG. 11 shows a hexagonal mesh and the interior angles at a vertex v, which are equal to π/3.

FIG. 12 shows a tetrahedral mesh that includes a tetrahedron with the interior dihedral angle α at an edge shown.

FIG. 13 shows a series of refinements of a simplicial manifold and a series of refinements of a regular grid.

FIG. 14 shows an adaptive refinement of the mesh underlying an oscillating manifold in which a distribution of energy in the sound pressure field of the oscillating manifold is localized at a vertex.

FIG. 15 shows an edge flip in a simplicial manifold.

FIG. 16 is a flowchart depicting a sequence of steps that is taken to adaptively refine the underlying mesh of an oscillating manifold utilizing an adaptive finite element method (AFEM) that minimizes a discretization error estimate η while utilizing as few discrete elements as possible.

FIG. 17 shows the Evolve-Adapt Loop of an oscillating manifold, wherein a Laplacian matrix is input to the evolution stage and used to evolve the oscillating manifold, and the sound pressure field is input to the adaption stage and utilized to refine the underlying mesh.

FIG. 18 shows a roughly disk-shaped triangulated domain with an absorbing boundary condition.

FIG. 19 shows a simplicial surface in the shape of an annulus that is transformed by a cut to produce a simplicial surface that is topologically a disk.

FIG. 20 is a flowchart depicting a sequence of steps taken in computing the boundary first flattening algorithm used in the coupling of OMs.

FIG. 21 shows a conformal mapping between two simplicial submanifolds that is achieved via a uniform domain by composition of a mapping h with an inverse mapping g⁻¹.

FIG. 22 shows a pair of tables that encode the global coupling information of a set of oscillating manifolds and a set of couplings between them.

FIG. 23 shows a table that encodes the set of couplings which are local to an oscillating manifold.

FIG. 24 shows a sequence of steps depicting the transmission of a manifold field signal between a source oscillating manifold and a target oscillating manifold, in which the sound pressure field data is enqueued as the source oscillating manifold evolves, and subsequently dequeued as the target oscillating manifold evolves.

FIG. 25 shows a cyber-physical system that consists of two computational platforms CP1 and CP2 which are connected to a network fabric via transmitters and receivers, and to the physical world via sensors and actuators.

FIG. 26 shows a computational platform that consists of a computer, a delay unit, a receiver, a transmitter, a sensor, and an actuator, and which is connected to a network fabric and a physical plant.

FIG. 27 shows an expanded view of a cyber-physical system consisting of two computational platforms that are each connected to a network fabric and physical plant.

FIG. 28 is a graphical illustration of the best master clock algorithm.

FIG. 29 shows a cyber-physical system in which the evolution of a mesh is computed in parallel by two computational platforms that each store data pertaining to a portion of the mesh, where there is one sub-portion of the mesh that is overlapping and about which data is stored by both computational platforms.

FIG. 30 shows the simplicial schema corresponding to the mesh of an oscillating manifold, and a set of tables and relationships between them, corresponding to this schema.

FIG. 31 shows a projection of a simplicial schema and the table corresponding to one portion of the mesh of an oscillating manifold.

FIG. 32 shows two simplicial schema and corresponding tables that are joined to produce one schema and one table.

FIG. 33 shows the union of two simplicial schema and correspondingly the union of their tables.

FIG. 34 shows an iterative triangulation procedure that constructs a triangulation from a set of points.

### DETAILED DESCRIPTION

The present invention provides methods, systems, and apparatuses that generate coupled cyber-physical acoustic media. In particular, the present invention teaches a discrete model of acoustic medium and computational schemes for their continuous evolution. A medium is modeled as a discrete (simplicial) manifold over which a function, the sound pressure field (SPF), evolves in time according to a discrete inhomogeneous wave equation (IWE). The IWE is formulated in terms of a cotangent approximation to the continuous Laplace-Beltrami operator of the manifold and, as the SPF evolves, the discrete manifold is concurrently iteratively retriangulated in order to better approximate the corresponding continuous manifold. The modelled spaces are referred to as oscillating manifolds (OMs).

Evolution of the OMs is computed using a numerical time-stepping scheme. Specifically, an AFEM is used to evolve each OM and periodically retriangulate the OMs using an a posteriori error estimator based on a local quantity measuring variation in the sound field. In one embodiment, the numerical scheme is parallelized over a plurality of processors by splitting the acoustic space into a set of subspaces which overlap, time-stepping the inhomogeneous wave equation within each of the pieces using shared boundary state at regions of overlap, and recombining the results.

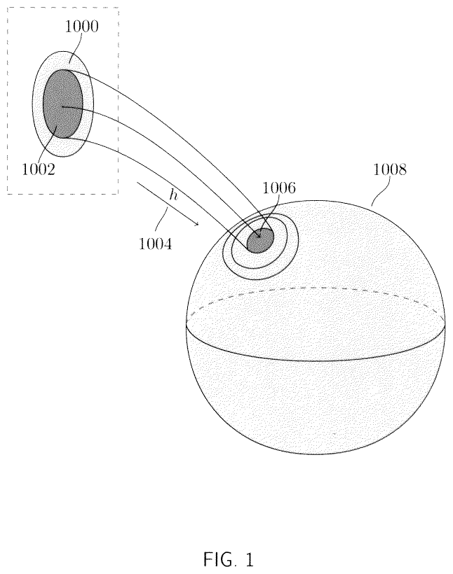

Interactions between coupled OMs (COMs) are modeled as occurring at interfaces that are submanifolds of the OMs. Pairs of submanifolds which provide couplings are mapped between using harmonic or conformal maps. The SPFs defined thereupon are thereby reparameterized and may subsequently be combined. For example, a pair of media may be generated that interact with each other in a directed manner, such that sound propagating in one medium is imparted to and propagates in the other; the interaction may then be modeled as an introduction into the IWE of the receiving medium of forcing terms measured over a boundary submanifold of the emitting medium and mapped onto the corresponding boundary submanifold of the receiving medium using a harmonic or conformal map. In FIG. 1), a disk-shaped OM (1000) is shown coupled at a disk-shaped submanifold (1002) via a coupling map (1004) to a sphere-shaped OM (1008) at a disk-shaped submanifold (1006).

An important aspect of the present invention is that networks or collections of OMs synchronously interact with one another, such that sound waves propagating in one or many of the media subsequently propagate in one or many of the other media. Synchronization of the OMs, whose evolutions may be generated by separate computational platforms, is achieved using clock synchronization and a safe-to-process analysis which allows for graceful failure and recovery of acoustic signals.

### Simplicial Complexes and Discrete (or Combinatorial) Surfaces

Topologically, a oscillating manifold is a simplicial manifold, i.e. a simplicial complex satisfying certain conditions. In particular, an abstract simplicial complex, C, is a collection of sets, called the simplices of the complex, that is closed under the operation of taking subsets (i.e., such that any subset of any of the sets is also an element of the complex); it is abstract in that the set of simplices encodes purely combinatorial information (and not geometric information). Equivalently, an abstract simplicial complex C is a collection of simplices, S, where a simplex is identified with a set of vertices, and where the set of vertices, or 0-simplices, which are singleton sets, is written V={v₀, v₁, . . . , vₙ}. A k-simplex s∈S is a set of (k+1) vertices, where k is referred to as the degree of the simplex. For example, the set {i, j} denotes an edge, or 1-simplex, the set {i, j, k} denotes a triangle, or 2-simplex, and the set {i, j, k, l} denotes a tetrahedron, or 3-simplex. In the following, we denote a simplex using the subscript of its vertices, for example writing eᵢⱼ for an edge, eᵢⱼ∈E, between vertices vᵢ and vⱼ; τᵢⱼₖ for a triangle, τᵢⱼₖ ∈F (where F is the set of triangles in the simplicial complex), between vertices vᵢ, vⱼ, and vₖ; etc. Thus, for example, an expression of the form aᵢ=Σ_{eij∈E} bᵢⱼ denotes the value of a quantity a, at a vertex i, that is obtained by summing a quantity b over all edges that share an endpoint at i. Similarly, aᵢ=Σ_{τijk∈F} bᵢⱼₖ denote the sum of a quantity over triangular faces incident to the vertex i. We use N(vᵢ) to denote the (1−) neighborhood of a vertex vᵢ, i.e., the set of vertices connected to vᵢ by an edge.

Note that, in identifying a simplex with an (unordered) set of vertices, we furthermore assume that it is ‘undirected’; thus, for example, a simplicial complex consisting of vertices connected by edges is the same as an undirected graph. (A directed simplex such as a directed edge would instead be represented by a list, or totally ordered set of vertices.) This point of view is natural when defining spaces which are discrete manifolds, since motion in such a space is not restricted locally to one direction or another.

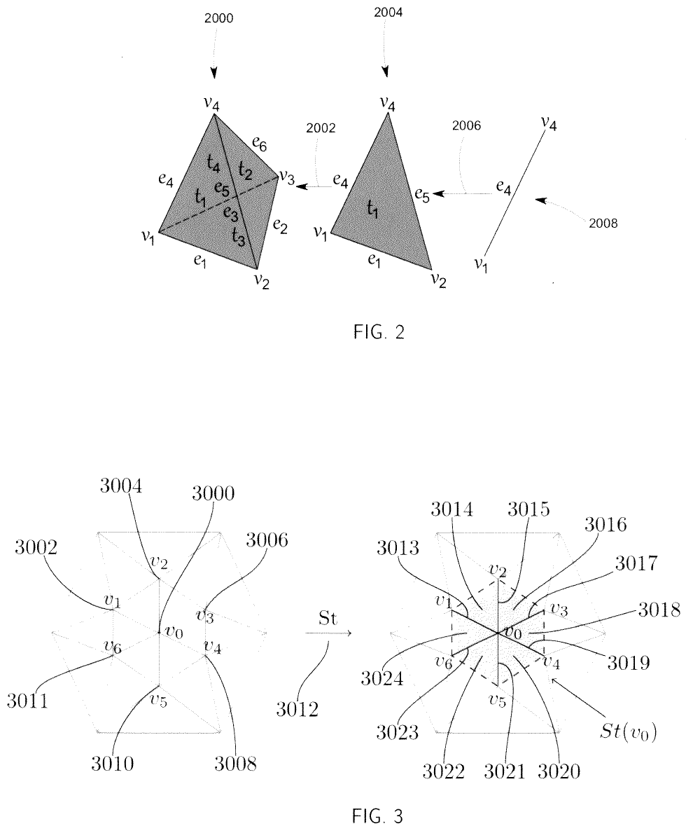

A subset of a simplex s is called a face of s, and a strict subset is called a proper face. In FIG. 2), the edge (2008) is shown included, via a map (2006), into the triangle (2004) of which it is a face, and the triangle (2004) is shown included, via a map (2002), into the tetrahedron (2000), of which it is face. A simplicial complex is called a pure k-simplicial complex if each of its simplices is a face of some k-simplex, possibly itself, in the complex.

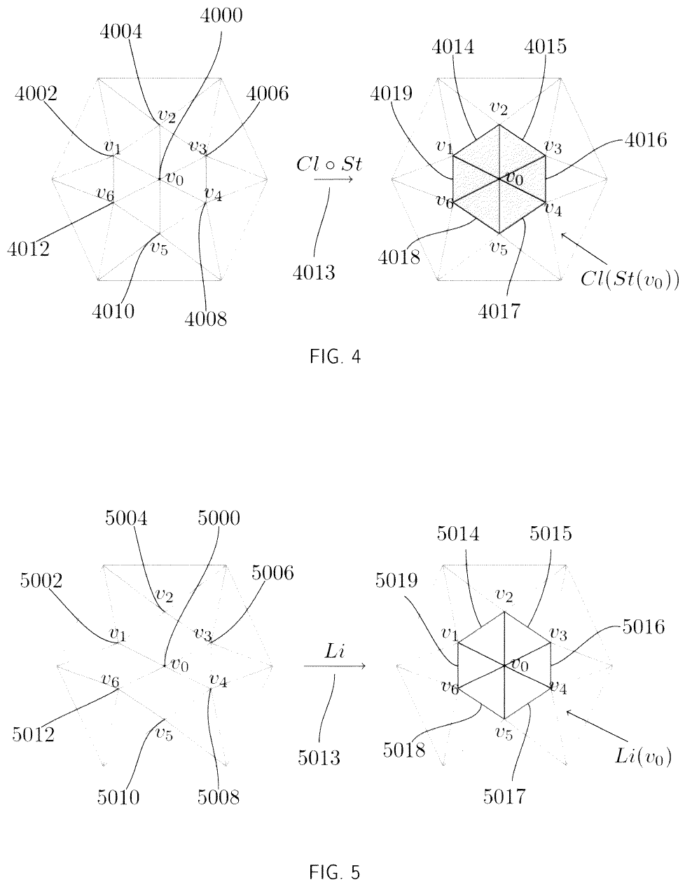

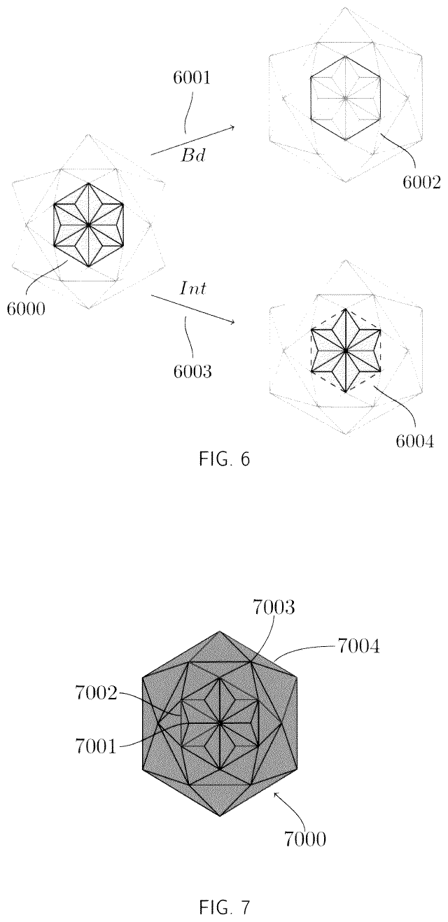

The condition that a simplicial complex be a discrete manifold can be stated in terms of elementary operations on simplices. The star, St(i), of a simplex i is the set of simplices containing any simplex in i. In FIG. 3), the star of the vertex (3000) with neighboring vertices (3002), (3004), (3006), (3008), (3010), and (3011) is shown. The star of the vertex (3000) is produced by the star operation (3012) applied to the vertex (3000) and includes the collection of edges (3013), (3015), (3017), (3019), (3021), and (3023), and collection of triangular faces (3014), (3016), (3018), (3020), (3022), and (3024), as shown. The star of i can be thought of as the smallest simplicial neighborhood of i, however St(i) is not, in general, a simplicial complex. The closure, Cl(K) of a set of simplices K is the smallest subcomplex of C containing K. In FIG. 4), the closure of the star of the vertex (4000) with neighboring vertices (4002), (4004), (4006), (4008), (4010), and (4012), as produced by the composition (4013) of the star and the closure operations is shown to include additionally, when compared to the star of the vertex, the edges (4014), (4015), (4016), (4017), and (4018). The link of a simplex i is Lk(i)=Cl(St(i)) \St(Cl(i)), where A\B denotes the set difference. In FIG. 5), the link of the vertex (5000) with neighboring vertices (5002), (5004), (5006), (5008), (5010), and (5012), as produced by the link operation (5013), is shown to consist of the edges (5014), (5015), (5016), (5017), (5018), and (5019). The boundary bd(M) of a pure k-subcomplex M⊂C is the set of all simplices s that are proper faces of exactly one simplex in M. The interior int(M)=M\bd(M) is the difference of M and its boundary. In FIG. 6), the boundary (6002), as produced by the boundary map (6001), and the interior (6004), as produced by the interior map (6003), of a pure simplicial k-complex (6000) are shown. A simplicial n-manifold, M, is a pure simplicial n-complex where Cl(St(i)) is a topological n-disk for every vertex i; equivalently, where the link of every vertex i, Lk(i), is a simplicial (n−1)-sphere, i.e. a simplicial triangulation of the n-dimensional sphere, equivalently a pure complex for which removing any vertex renders the space contractable to a point. In FIG. 7), a disk-shaped simplicial 2-manifold (7000) is shown, wherein for example the link (7002) of the vertex (7001) is a simplicial 1-sphere, and the link (7004) of the vertex (7003) is a simplicial 1-sphere. A simplicial manifold may also be referred to as a simplicial hypersurface; the term simplicial surface will be reserved to mean simplicial 2-manifold, i.e., where the link of every vertex is a single loop of edges. See [K. Crane, “Digital Geometry Processing with Discrete Exterior Calculus”, in ACM SIGGRAPH, 2013], which we incorporate by reference, for more details on simplicial surfaces and elementary simplicial operations in geometry processing.

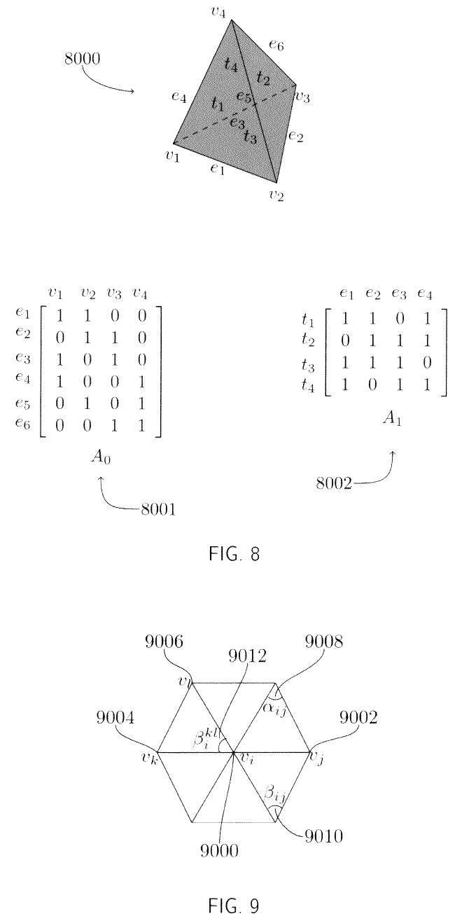

Computationally, the topological data of an abstract simplicial complex may be encoded using adjacency matrices to represent which simplices in the complex are connected. Specifically, for the set of k-simplices, for each k, each k-simplex may be given a unique index, and the k^{th} adjacency matrix, Aₖ, may be formed having as many columns as there are k-simplices in the complex, and as many rows as there are (k+1)-simplices, and having as entries 1 wherever a k-simplex is contained in a (k+1)-simplex, and 0 elsewhere. In FIG. 8), the adjacency matrix (8001) which maps between vertices and edges of the tetrahedron (8000) and the adjacency matrix (8002) which maps between edges and triangles of the tetrahedron (8000) are shown. Other data structures, such as the halfedge mesh, can also be used to encode simplicial manifolds.

### Geometry and Discrete Metric

An abstract simplicial complex represents the topological, but not the geometric information about a surface. An abstract simplicial complex may be augmented with additional information of a geometric nature, and the resulting data structure, which stores both topological and geometric information about the manifold is referred to as a mesh. The geometry of the surface may be encoded extrinsically, by associating each vertex with coordinates, or intrinsically, by assignment of edge lengths to each 1-simplex according to a discrete metric, where the assignment of positive edge lengths l:E→ [symbol] _{>0} satisfies the triangle inequality strictly in each triangular face:

lᵢⱼ+lⱼₖ>lₖᵢ ∀ijk∈F (1)

In other words, for all triangles in the complex, the sum of the lengths of any two of the edges is greater than that of the third edge. This condition excludes degenerate triangles where equation 1 is an equality. Such an assignment of edge lengths defines a piecewise Euclidean (or flat) metric over each simplex of S. For a triangle r₁₂₃ ∈F with vertices r₁, r₂, r₃ (where we use bold script to denote vectors or position), the coordinates of a point r within the triangle can be given using barycentric coordinates, i.e. as a unique convex combination

r=λ₁r₁+λ₂r₂+λ₃r₃, (2)

where the numbers λ₁, λ₂, λ₃≥0 are all positive and sum to 1, λ₁+λ₂+λ₃=1. At each triangle τᵢⱼₖ, the discrete metric determines the interior angle βᵢ^{jk}, βⱼ^{ki}, βₖ^{ij} at vertices i, j, and k. In FIG. 9), an interior angle (9012) at a vertex (9000) that is in the triangle formed by the vertices (9000), (9004), and (9006) is shown. Also shown are the two angles (9008) and (9010) opposite the edge between vertices (9000) and (9002).

Functions may be defined over a simplicial manifold, and stored in the mesh data structure. For example, a function might be a complex-valued function defined at the vertices of the simplicial complex, i.e., ƒ:V→ [symbol] . An important example of a function at the vertices of a simplicial manifold is a coordinate function ƒ:V→ [symbol] ³, which assigns to each vertex a position in a space, such as in 3-dimensional physical space. In this case, the discrete metric, and so the geometry of the surface, may be determined by taking the length of an edge ij to be the Euclidean distance, lᵢⱼ=|ƒⱼ−ƒᵢ|.

In certain cases, a discrete metric may not capture the intrinsic geometry of a smooth surface from which it is derived. For example, the simplicial manifold may not be triangulated finely enough. (This could happen, for example, in the case of a simplicial complex constructed from a sensor array embedded in a physical environment if there are only a few sensors.) Accordingly, it may be desirable to improve the quality of a simplicial manifold modelling a smooth surface. The present invention provides a A method of achieving this using elementary mesh operations based on an a posteriori error estimator which involves and minimization of a discrete energy, as described below.

In addition to scalar functions, vector fields such as a normal vector field may be defined over a simplicial manifold. In particular, a unit normal can be defined at a triangular face, such as by using the cross product and right-hand-rule. If such an assignment can be made to each triangular face, that is globally consistent with respect to the ordering (winding) of vertices, then the manifold is orientable (examples of nonorientable manifold include a Mobius strip and Klein bottle). The focus of the present invention is on orientable manifolds. In order to define unit normal vectors at vertices, a number of approaches may be taken, the simplest of which is to define it as the normalized sum of the unit normals at the triangular faces incident to the vertex. However, normal vectors produced in this manner may not well-approximate the corresponding normal vectors of the smooth surface being approximated by the mesh. A related approach that produces normal vectors which are more independent of the particular discretization is to weight the face normals by the interior angles formed between them and the central vertex. This results in

$${N}_{θ} : = {\sum }_{i} {θ}_{i} {N}_{i}$$

Amongst other approaches is included the approach based on the sphere-inscribed polytope, whereby the normal at a vertex pᵢ is expressed in coordinates in terms of the edge vectors eⱼᵢ=pⱼ−pᵢ, where the pⱼ are the neighboring vertices of pᵢ, as

$${N}_{S} : = \frac{1}{c} {\sum }_{j = 0}^{n - 1} \frac{{e}_{j} \times {e}_{j + 1}}{\vert {e}_{j} {\vert}^{2} \vert {e}_{j + 1} {\vert}^{2}}$$

where x is the vector cross product, and c is [−]. Yet another approach to defining unit normals is based on the area gradient of triangles of a mesh. Specifically, for a smooth surface M in [symbol] ³, i.e. which is given by a function ƒ assigning vertices positions in 3-dimensional Euclidean space, ƒ:M→ [symbol] ³, we have that Δƒ=2HN, where Δ is the Laplace-Beltrami operator (defined later on), and H is the mean curvature; the unit surface normal N is computed by applying a discrete Laplace operator (such as is given by the cotangent approximation below) to the vertex positions and then normalizing the resulting vector.

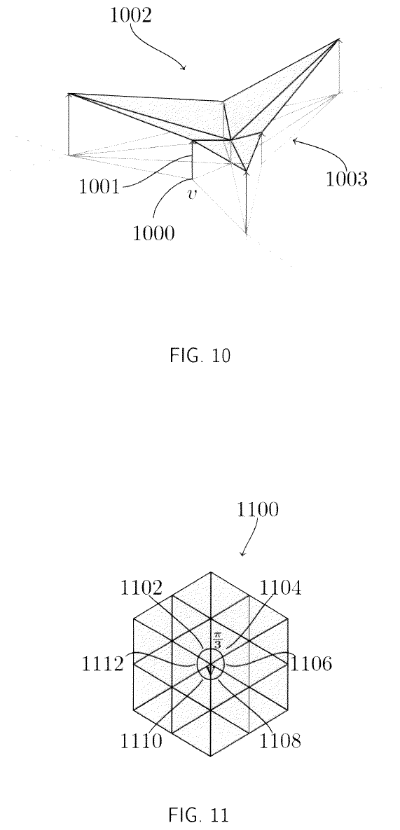

Given the unit normal vector field on a (orientable) simplicial surface, the velocity vector field or just velocity field of the surface is the vector field whose value at each vertex is the scalar-vector product of the unit normal vector and the value of the SPF at the vertex. The value of the velocity field at a vertex is also called the height at the vertex, and the velocity field may also be called the height field. The velocity field can be thought of as representing the instantaneous deformation of the surface in the normal direction. In FIG. 10), a velocity field (1002) associated to an underlying simplicial surface (1003) is shown, as well as the height (1001) at a vertex (1000). The unit normal vector field and the velocity vector field are also stored in the mesh data structure of the present invention.

### Discrete Differential Operators and the Inhomogeneous Wave Equation

Dynamically, an oscillating manifold is a field that evolves according to a discrete form of the inhomogeneous wave equation. The differential operator at the heart of any wave equation is the Laplace operator, or just Laplacian, denoted Δ. It is a second-order differential operator, and is used to define Laplace's equation, which for a continuous real-valued function u is

Δu=0. (3)

The Laplacian Δ is defined to be the sum of second-order partial derivatives. For example, in [symbol] ³ in Cartesian coordinates, we have that

$$Δ = \frac{{\partial }^{2}}{\partial {x}^{2}} + \frac{{\partial }^{2}}{\partial {y}^{2}} + \frac{{\partial }^{2}}{\partial {z}^{2}} .$$

Solutions to equation (3) are called harmonic functions (not to be confused with harmonic mappings), and can be written as sums of sinusoidal and cosinusoidal functions.

A generalization of equation (3) is Poisson's equation, which reads

Δu=ƒ, (4)

where ƒ is a continuous real-valued function referred to as a forcing term. A related differential equation is the heat equation, which for a continuous real-valued function u defined at each pair of points (t, p), where t∈ [symbol] is time and p∈M is a point on a manifold M, i.e, u:M× [symbol] → [symbol] , is

$$\frac{\partial u}{\partial t} := \dot{u} ( t ) = α \cdot Δ u ( t )$$

where α is a constant, called the thermal diffusivity. The heat equation says that the rate of change of the function u at a time t is given by the Laplacian of the spatial part of u.

We now turn to the inhomogeneous wave equation (IWE). In the case of a real-valued (continuous) function u: [symbol] ³× [symbol] → [symbol] of 3-D Euclidean space and time, the IWE is written

$$\frac{1}{{c}^{2}} \frac{{\partial }^{2} u}{\partial {t}^{2}} ≡ ü ( x , y , z , t ) = Δ u ( x , y , z , t ) + f ( x , y , z , t ) \qquad ( 5 )$$

where ƒ: [symbol] ³× [symbol] → [symbol] is a forcing term of similar dimensions to u, and c∈ [symbol] is the wave speed. Generalizing to an arbitrary smooth manifold M, setting c=1 for the sake of simplicity, equation, and using p∈M to denote a point on the manifold, (5) becomes

ü(p,t)=Δ_{LB}u(p,t)+ƒ(p,t) (6)

where Δ_{LB} is the Laplace-Beltrami operator, or Laplacian for the manifold M, which generalizes from the Laplacian Δ in Euclidean space (since the space [symbol] ⁿ is a manifold).

In the discrete case, the manifold is parameterized spatially in terms of the vertices, edges, and higher-order simplices of a mesh. Discrete versions of the foregoing differential equations can be produced using corresponding formulations of the discrete Laplace-Beltrami operator. This is achieved using a discrete form of Δ_{LB} referred to as the simplicial Laplacian or cotangent Laplacian operator L, which can be written purely in terms of the angles formed between adjacent edges, or triangles, in the tesselation. It is defined in two dimensions by the cotangent formula

$${( Δ u )}_{i} : = \frac{1}{2 {A}_{i}} {\sum }_{{e}_{i j}} ( cot {α}_{i j} + cot {β}_{i j} ) ( {u}_{j} - {u}_{i} ) \qquad ( 7 )$$

where the sum is indexed over all edges eᵢⱼ incident to vertex i, vⱼ∈ [symbol] (vᵢ), Aᵢ is an area associated to the vertex vᵢ, such as one third the sum of the areas of the triangles containing vᵢ, and the angles αᵢⱼ, βᵢⱼ are the two interior angles opposite to eᵢⱼ. For example, FIG. 11) shows a hexagonal mesh (1100) where at the vertex v shown at center each of the angles (1102), (1104), (1106), (1108), (1110), and (1112) at the vertex is equal to

$$\frac{π}{3} .$$

For such a mesh, at which at each vertex six edges meet forming equilateral triangles, and letting all edges be of length

$$\frac{2}{\sqrt{2} \sqrt{3}} ,$$

the cotangent formula (7) reproduces the formula for the graph Laplacian, defined simply by:

$${( Δ u )}_{ii} = deg ( {υ}_{i} ) , {L}_{ij} = \{ \begin{matrix}- 1 , & j ∈ 𝒩 ( {υ}_{i} ) \\ 0 & else\end{matrix} .$$

This can be seen by noting that

$$\frac{1}{2 {A}_{i}} {\sum }_{{e}_{i j}} ( cot {α}_{i j} + cot {β}_{i j} ) ( {u}_{i} - {u}_{j} )$$

$$= \frac{1}{2 \sqrt{3} \cdot \frac{\sqrt{3}}{4} {( a b c )}^{( 2 / 3 )}} ( 6 {u}_{i} - {\sum }_{{e}_{i j}} {u}_{j} )$$

$$= ( 6 {u}_{i} - {\sum }_{{e}_{i j}} {u}_{j} )$$

$$where T = \frac{\sqrt{3}}{4} {( a b c )}^{( 2 / 3 )}$$

is the area of an equilateral triangle with edge lengths a, b, c, which for side length

$$a = b = c = \frac{2}{\sqrt{2} \sqrt{3}} is \frac{4}{2 \cdot 3} .$$

The cotangent formula can be encoded in matrices, C, G∈ [symbol] ^{|V|×|V|}, where |V| is the number of vertices of the mesh, sometimes referred to as the stiffness matrix (or weak Laplacian) and mass matrix, which encode the cotangent weights and the area-based normalizing factors, respectively. The matrix C has entries

$${C}_{ij} = - {w}_{ij} {C}_{ii} = {\sum }_{j ∈ {N}_{i}} {w}_{ij} \qquad ( 8 )$$

where wᵢⱼ is the cotangent weight given by

$${w}_{ij} = {\sum }_{{τ}_{ijk}} \frac{1}{2} cot {θ}_{ij} \qquad ( 9 )$$

where the sum is taken over all triangles τᵢⱼₖ containing the edge eᵢⱼ (which will be two triangles if the edge lies in the interior of the domain, and one triangle if it is at the boundary), and the angle θᵢⱼ is the angle opposite the edge eᵢⱼ in the triangle τᵢⱼₖ. For the mass matrix G, the matrix may be taken to be the identity, however this may not accurately represent the distribution of mass at the different points, if the surface is curved (as dirac Delta functions located at the vertices will be scaled differently). A more principled choices for G that is mesh-dependent is the vertex lumped mass matrix, which is the diagonal matrix with i^{th} entry equal to one third the sum of the areas of the triangles incident on vertex i

$${( {G}_{lumped} )}_{ii} = \frac{1}{3} {\sum }_{ijk} {A}_{ijk} \qquad ( 10 )$$

where Aᵢⱼₖ is the area of the triangle with vertices ijk. Another choice is the Galerkin mass matrix

$${( {G}_{Galerkin} )}_{ii} = \frac{1}{6} {\sum }_{ijk} {A}_{ijk} {( {G}_{Galerkin} )}_{ij} = \frac{1}{12} {\sum }_{ijk} {A}_{ijk} \qquad ( 11 )$$

The cotangent Laplacian operator can then be written as L=G⁻¹C. In the sequel, we sometimes implicitly identify the matrix L with the matrix of cotangent weights, C, unless the mass matrix is explicitly relevant. We furthermore sometimes omit the normalizing factor of

$$\frac{1}{2 {A}_{i}}$$

in the cotangent formula (7). The matrices L, C, and G that are associated to a simplicial manifold S may be stored in the mesh data structure of an oscillating manifold, along with the discrete metric. Likewise, the forcing terms ƒ may be stored over the mesh.

Thus, for example, in the discrete setting Poisson's equation (4) becomes

Lu=ƒ (12)

where u, θ∈ [symbol] ^{|V|} are two vectors, representing functions defined at the vertices of M. Similarly, the discrete version of the IWE, equation (6), then follows from the above definitions as

$$\frac{{d}^{2} u}{{dt}^{2}} = Lu + f . \qquad ( 13 )$$

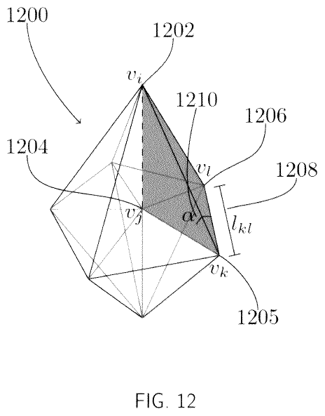

The foregoing construction of the discrete Laplace operator can be straightforwardly extended to higher dimensions, as shown in [Crane, The n−D Cotangent formula]. Generally for an n-dimensional simplicial manifold with vertices |V| and edges |E|, the discrete Laplacian is a matrix L∈ [symbol] ^{|V|×|V|} with entries as in definition (8), but with edge weights

$${w}_{ij} = \frac{1}{n ( n - 1 )} {\sum }_{ij ∈ σ} {V}_{{\overline{σ}}_{ij}} cot {θ}_{{\overline{σ}}_{ij}} \qquad ( 14 )$$

where the summation is over all n-simplices σ containing edge ij, σ̅ᵢⱼ is the (n−2)-simplex obtained by removing vertices i and j from σ, V_{σ̅}_{ᵢⱼ} is the volume of σ̅ᵢⱼ, and θ_{σ̅}_{ᵢⱼ} is the internal dihedral angle at σ̅ᵢⱼ. The 1-dimensional edge weights are simply

$${w}_{ij} = \frac{1}{{l}_{ij}} ,$$

where lᵢⱼ is the length of the edge ij. A standard choice of mass matrix is

$${G}_{ii} = \frac{1}{n + 1} {\sum }_{i ∈ σ} {V}_{σ} \qquad ( 15 )$$

where the sum is over all n-simplices σ containing i, and V_{σ} denotes the volume of σ. For example, in 3D, the cotangent matrix is defined by

$${C}_{i , j} = - {w}_{ij} {C}_{i , i} = - {Σ}_{ij} . {C}_{ij} \qquad ( 16 )$$

$$where$$

$${w}_{ij} = \frac{1}{6} {\sum }_{ijkl} {l}_{kl} cot {θ}_{kl}^{ij}$$

in which the sum is taken over all tetrahedra (3-simplices) containing the edge ij, and θₖₗ^{ij} is the interior dihedral angle at edge ij of the tetrahedron ijkl. FIG. 12) shows a tetrahedral mesh (1200) and a tetrahedron with vertices (1202), (1204), (1205), and (1206), and having an interior dihedral angle (1210) at an edge (1208). In the following, we sometimes present formulas involving differential operators, or their matrix representations, which are two-dimensional; however, it should be understood that these operators and matrices have analogues in higher dimensions.

### Function Decomposition Using the L-B Operator Spectrum

In certain aspects of the present invention, the spectrum of the matrix L is used. That is, the matrix factorization L=Q⁻¹ΛQ is computed, where Q is the matrix of eigenvectors and Λ is a diagonal matrix of corresponding eigenvalues. Given a function u:V→ [symbol] defined over a mesh with cotangent Laplacian L, the spectral decomposition of u is then given in terms of coefficients by the vector û, whose elements are given by inner products of the eigenvectors and the function u, as

$$\hat{u} [ i ] = u \cdot {q}_{i} = {\sum }_{j = 1}^{\vert V \vert} u [ j ] \cdot {q}_{i} [ j ] \qquad ( 17 )$$

where qᵢ is the i^{th} eigenvector of the matrix Q. The function u can be reconstructed from its spectral representation as a linear superposition of the eigenvectors, weighted by their inner products with u itself, as

$$u [ i ] = {\sum }_{i}^{\vert V \vert} \hat{u} [ i ] \cdot {q}_{i} . \qquad ( 18 )$$

### Mesh Refinement and Improvement

A mesh may not accurately represent the intrinsic geometry of the space which it is meant to model. For example, it can be problematic if the edge weights of the mesh are constructed from a Euclidean embedding of a real world sensor array, such as a spherical sensor array, using the Euclidean distance metric and if not enough sensors were used. Or, analogously, it can be problematic if a cyber-generated mesh created in order to approximate a smooth space was not triangulated finely enough. Accordingly, it may be desireable to improve the quality of a mesh modelling a smooth surface. This can be done in a variety of ways.

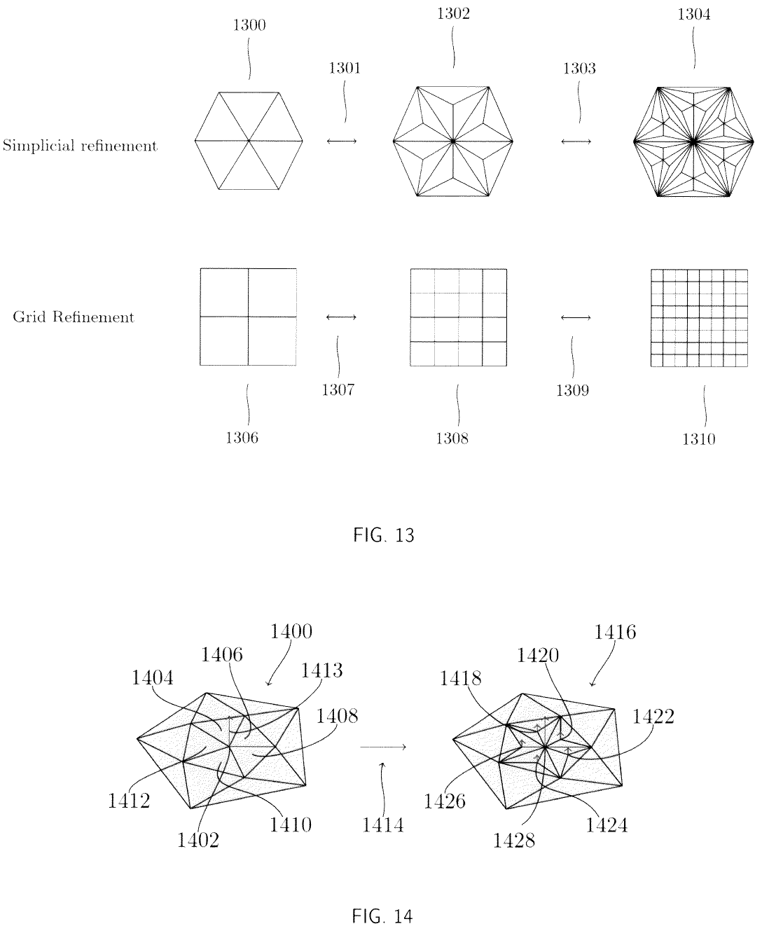

An example of refinement (1301) between simplicial manifolds (1300) and (1302) and another refinement (1303) between simplicial manifolds (1302) and (1304), as well as of a refinement (1307) between regular grids (1306) and (1308) and another refinement between regular grids (1308) and (1310) is shown in FIG. 13). According to the present invention, a mesh is retriangulated in order to minimize an error between a discrete energy, known as the discrete Dirichlet energy, defined over the current mesh, and an (unknown) minimal energy which could be attained. To perform this in a computationally optimum manner, the present invention teaches a method where the number of simplices in the mesh is minimized, while maintaining the error below a maximum amount.

First, for a surface S with boundary, we define the space of admissible states, Û, as the space of continuous functions û whose values coincide with those of the given function (the SPF) on the boundary of the space (if it has boundary), and which are piecewise linear on every triangle. If the manifold is closed, i.e. has no boundary, then the admissibility condition can be modified slightly, such that a function is admissible if it integrates to zero, its square integrates to one, and its product with any other function found to satisfy the first two conditions is zero. This excludes, in particular, the function which is zero everywhere.

For a function u:V→ [symbol] , the energy associated to it is

$$ℰ ( \hat{u} ) := {\sum }_{T} {\int }_{T} ∇ {\vert \hat{u} ( x , y ) \vert}^{2} dxdy \qquad ( 19 )$$

where T is a triangle of the mesh. The finite energy minimization problem is then

compute \hat{Φ}:=min{ε(û):û∈Û} (20)

That is, we search for a minimizing function û∈Û such that ε(û)=\hat{Φ}.

A solution to the preceding problem can be formulated numerically in terms of an error term

ê:=|\hat{Φ}−Φ| (21)

which is the difference between the computed energy \hat{Φ} of the existing mesh, and the true, but unknown, energy corresponding to an ideal mesh. One approach to minimizing this error is to refine the mesh such that more finite elements (e.g., simplices) are used and so that they are distributed uniformly. However, in most cases this approach will produce far more elements than is necessary. Instead, a discretization is sought that is optimal not only with respect to the error ē, but also with respect to the number of discrete elements of the mesh, which number ideally is kept low to satisfy implementation memory and processing requirements. The design of an efficient mesh then comes down to the design of a mesh with as few finite elements as possible, but such that the error e is smaller than a tolerance ϵ (which may be application-dependent, and can be set by the user).

The present invention provides the following algorithmic approach to efficient mesh generation. The approach enjoys two important properties. Firstly, it generates efficient meshes automatically, i.e. meshes are self-adaptive. Secondly, it is based on a local quantity, and so is ammenable to parallelization. Hence, the algorithm does not require constant supervision by the user, and furthermore is suited for use in a distributed real-time system.

The algorithm is based on an a posteriori estimator, η, of the error term ê. The estimator is said to be a posteriori since it is computed after the function u is already known, and is used to indicate which finite elements are to be refined at the next step. In the case of a simplicial surface, the estimator is evaluated locally, triangle-by-triangle, according to

$$η := {\sum }_{T} {\sum }_{ij} {( {l}_{ij} )}^{2} \cdot {\vert {[ ∇ \hat{u} ]}_{ij} \vert}^{2} \qquad ( 22 )$$

where ij is an edge of triangle T, lᵢⱼ is the length of edge ij, and [∇û]ᵢⱼ denotes the jump of the piecewise constant gradient, of the function û, from one of the triangles adjacent to the edge ij to the other. Recall that for a function ƒ:V→ [symbol] defined at the vertices of a simplicial surface, ƒ extends linearly to the interior of each simplex σ as

$${\tilde{f}}_{σ} ( r ) = {\sum }_{{υ}_{i} ∈ σ} {λ}_{i} {f}_{i} ,$$

where r is a point in σ, the vᵢ are vertices of σ, and the λᵢ are the barycentric coordinates of the point r with respect to the vᵢ. Thus the gradient of \tilde{ƒ} is constant on the interior of each face σ, and can be defined per-face, or at the centroid c_{σ} of each face σ. For a triangle ijk, the gradient ∇ƒᵢⱼₖ is defined as

$$∇ {f}_{ijk} = ( {f}_{j} - {f}_{i} ) \frac{{( {υ}_{i} - {υ}_{k} )}^{⊥}}{2 {A}_{ijk}} + ( {f}_{k} - {f}_{i} ) \frac{{( {υ}_{j} - {υ}_{i} )}^{⊥}}{2 {A}_{ijk}} \qquad ( 23 )$$

where vᵢ, vⱼ, vₖ are the vertices of the triangle, Aᵢⱼₖ is its area, and e_{ab}^{⊥}=(vₐ−v_{b})^{⊥} denotes the edge e_{ab} between vertices a and b, rotated 90° in the plane of the triangle.

Intuitively, places in the mesh where the term Σᵢⱼ(lᵢⱼ)². |[∇û]ᵢⱼ|² is large correspond to regions where there are large kinks in the mesh. These regions can then be isolated for retriangulation. In one example of how to do this, a subset S of the triangles in the mesh may be computed that contains as few triangles as possible while maintaining that the sum of the contributions to the estimator η coming from triangles in S is larger than a percentage θ of the total error, as in

$${\sum }_{{T}^{′}} {\sum }_{ij} {( {l}_{ij} )}^{2} \cdot {\vert {[ ∇ \hat{u} ]}_{ij} \vert}^{2} \geq θ η \qquad ( 24 )$$

where now T′ is in S, i.e. T′∈S. This is known as the Dorfler marking strategy. Solving for the desired subset T′ of triangles is a standard optimization problem, and can achieved, for example, by sorting the triangles of the mesh in decreasing order of their contribution to the error (which can be done in n log n time), and then choosing as the subset the first sequence of vertices with total gradient change quantity greater than the given percentage. The triangles in the subset are then refined, for example using barycentric refinement, in which case a new vertex is inserted at the barycenter of the simplex, i.e. the point p_{b} at which the weights λᵢ in the barycentric coordinate parameterization defined by equation (2) are all equal. An example of an adaptive refinement (1414) of the mesh (1400) is shown in FIG. 14), in which the red arrow (1413) represents a source of energy in the mesh SPF localized at the vertex (1402) incident to the triangles (1404), (1406), (1408), (1410), and (1412). The refined mesh (1416) includes the new vertices (1418), (1420), (1422), (1424), and (1426) incident to the vertex (1428).

Conversely, if a mesh includes more discrete elements than needed or can be afforded, then the mesh is coarsened, by selecting a subset of triangles the aggregate of whose contributions to the total error is below a certain percentage, but which includes as many triangles as possible, and then removing vertices of those triangles. Any addition or removal of vertices naturally modifies the adjacency and Laplacian matrices of a mesh, and in the case of insertions functions are linearly interpolated as usual, using the barycentric weights, in order to obtain values over the new points. It has been shown that refining a mesh according to the scheme described above reliably minimizes the energy.

The adaptive refinement procedure may also be used for a tetrahedral mesh. Recall that the formula for the gradient of a function on However, the a tetrahedral mesh, analogous to 23 for triangle meshes, is defined per tetrahedral face, ijkl, as

$$\begin{matrix}∇ {f}_{ijkl} = ( {f}_{j} - {f}_{i} ) \frac{( {υ}_{i} - {υ}_{k} ) \times ( {υ}_{l} - {υ}_{k} )}{2 {V}_{ijkl}} \\ + ( {f}_{k} - {f}_{i} ) \frac{( {υ}_{i} - {υ}_{l} ) \times ( {υ}_{j} - {υ}_{l} )}{2 {V}_{ijkl}} \\ + ( {f}_{l} - {f}_{i} ) \frac{( {υ}_{k} - {υ}_{i} ) \times ( {υ}_{j} - {υ}_{i} )}{2 {V}_{ijkl}}\end{matrix} \qquad ( 25 )$$

where vᵢ, vⱼ, vₖ, vₗ are the vertices of the tetrahedron, x denotes the cross-product, and Vᵢⱼₖₗ is the tetrahedral volume,

$${V}_{ijkl} = \frac{1}{3} Ah ,$$

where A is any base triangle and h is the length of the corresponding altitude. The error estimator η_{Tet} is then given by integrating the jump of the piecewise-constant gradient across each triangular face of a tetrahedron and weighted by the area of the face, as

$${η}_{Tet} := η := {\sum }_{Γ} {\sum }_{ijk} {( {A}_{ijk} )}^{2} \cdot {\vert {[ ∇ \hat{u} ]}_{ijk} \vert}^{2} \qquad ( 26 )$$

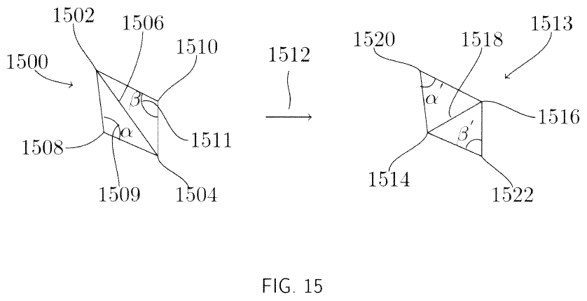

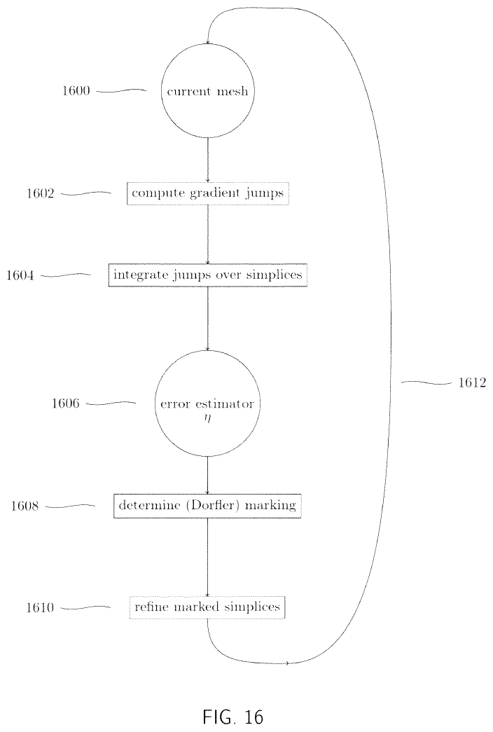

Other processes can also be used to improve the quality of a mesh. In particular, a local edge-flipping algorithm can be used to cause the mesh of a simplicial surface to converge towards a Delaunay triangulation. Specifically, an edge flip may be performed whenever the sum of the two angles opposite an edge eᵢⱼ exceeds π. In FIG. 15), an edge flip (1512) that flips an edge (1506) between vertices (1502) and (1504), having opposite angles (1509) and (1511) at vertices (1508) and (1510) of the triangulation (1500) is shown. The result of the edge flip (1512) is a new triangulation with edge (1518) between vertices (1514) and (1516), having opposite angles at vertices (1520) and (1522). A mesh that satisfies the Delaunay condition has many nice properties that can improve the quality of numerical time-stepping schemes for evolution of fields defined over the mesh.

An overview of the adaptive refinement process is shown in the flowchart FIG. (16), wherein a current mesh (1600) is used as input in a step (1602) that computes the gradient jumps, and then in a step (1604) the jumps are integrated over simplices, determining an error estimate (1606), which is used as input in a step (1608) that determines a marking for refinement, and then in a step (1610) the marked simplices are refined, and finally the resulting mesh becomes, per the arrow (1612), the current mesh.

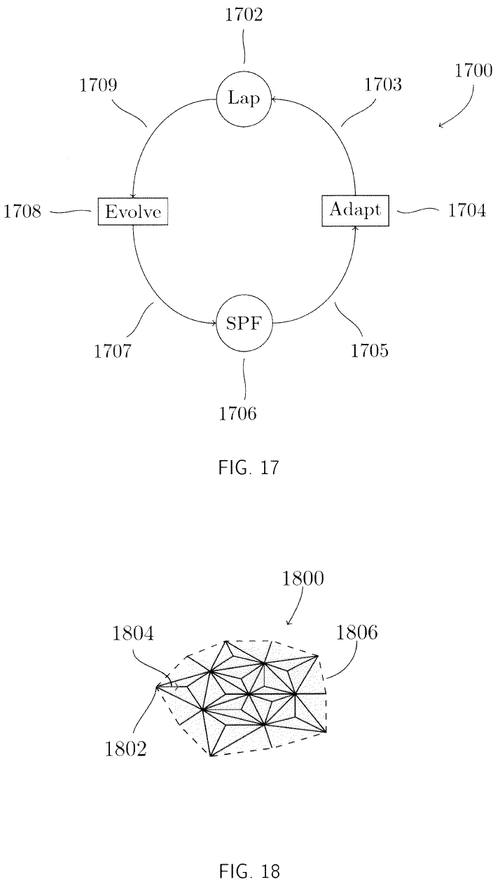

In the present invention, the refinement process described above is used repeatedly, e.g. periodically, in a self-adapted algorithm referred to as the AFEM to refine the mesh underlying an OM as the SPF of the OM changes (both in response to the diffusion process which is driven by the discrete Laplace operator, as well as due to perturbation by any forcing terms). Thus, an OM evolves in a cyclic feedback loop, or ‘evolve-adapt’ loop (1700), as shown in FIG. 17, wherein the Laplace matrix (1702) of a mesh is input per the arrow (1709) to a step (1708), wherein it is used to evolve the sound field of the OM, resulting per the arrow (1707) in a new sound field (1706), which is then input per the arrow (1705) to a step (1704), wherein it is used to adaptively refine the mesh, resulting per the arrow (1703) in a new Laplace matrix. Thus, the OM mesh is periodically (for example, at each time-step) adaptively refined, which affects the evolution of the OM as it is driven by the cotangent approximation to the L-B operator of the OM underlying simplicial manifold, which depends on the mesh. In the other direction, evolution of OM affects the distribution of energy in the scalar field, which affects how the OM mesh is refined.

### Absorbing Boundary Conditions

Manifold domains of infinite extent can be simulated on a computer using absorbing boundary conditions (ABCs). Various types of absorbing boundary conditions exist, including first-order and higher-order differential operator-based methods. Generally speaking, the methods are used to achieve the annihilation of outgoing waves from a finite computational domain. An example of a higher-order method is the improved Higdon ABC. Other methods for simulation of unbounded domains include the perfectly matched layer (PML).

A simple, first-order ABC is defined as follows. Let u:M→ [symbol] be a function on a manifold domain with boundary, and let

$$\frac{d}{dn} u$$

be the (inward-facing) normal derivative of u. Then the ABC is computed by imposing that, at the boundary of the domain, the first-order time-derivative of the function is equal to the normal derivative, i.e.

$$\frac{d}{dt} u - \frac{d}{dn} u = 0$$

and computed using standard finite-differences. All other nodes in the interior are processed normally. A disk-shaped triangulated domain (1800) with an ABC (1806) is shown in FIG. 18), wherein there is also depicted an inward-facing normal vector (1804) at a boundary vertex (1802). An ABC allows for computation of the evolution of an OM that has a boundary as if it were unbounded. This can be useful since the OM will not resonate (to the extent that the ABC is effective) and will vibrate freely. As a consequence, the spectrum of a signal measured over the OM domain will not be convolved the spectrum of the L-B operator of the manifold itself. In a musical application, a manifold might be modeling the membrane of a drum that is clamped at its boundary, and application of an ABC changes the drum into a freely vibrating membrane.

The ability to apply an ABC to compute the evolution of an OM as if it were of infinite extent may be useful, for example, in scenarios where the mesh representing the OM corresponds to an array of sensors having or array of actuators located in an outdoor space, or in a space where the propagation of sound waves over short distances, and not their reflections off of the boundary of the space, is important. An example may be a large room in which there is a group of speakers located close to one another. In such a case, an ABC may be imposed such that the speakers voices can be clearly heard, and reverberations of their speech waveforms off of the walls of the room are effectively canceled. Absorbing boundary conditions can, more generally, be utilized to ‘sculpt’, or architect an acoustic domain, e.g. to establish curves that may act as waveguides.

### Interactions Via Forcing Terms

A central aspect of the present invention is that the forcing term ƒ in equation (13) may be comprised of various component terms ƒᵢ, i.e.,

$$f = {\sum }_{p}^{P} {f}_{p} + {\sum }_{c}^{C} {f}_{c} , \qquad ( 27 )$$

where the first sum is for the contributions from physical forces ƒₚ and the second sum is the contribution from cyber forces ƒ_{c}, and that the forcing terms may be pulses or may be extended in time. A physical forcing term ƒₚ in a collection P of physical sources may originate from a pressure sensor (i.e., a microphone) that is embedded in analog media in the physical world. Cyber forcing terms ƒ_{c} in a collection C of cyber sources originate digitally from cyber-generated oscillating manifolds. For example, two forcing terms, ƒₚ and ƒ_{c} may be received, the first, ƒₚ, from a microphone array in the physical world, and the second, ƒ_{c}, in digital format from an OM. In the following, we speak of an OM from which a forcing term ƒ_{c} is being generated as a source OM, and an OM which is affected by the forcing term ƒ_{c} as a target OM.

Note that a conventional stream of audio, e.g. a stream of pulse code modulation (PCM), can be seen as a forcing term at a trivial cyber-generated OM having no spatial extent (since a point is a zero-dimensional manifold). More generally, a disjoint set of streams of PCM can be considered as a set of forcing terms coming from a single OM having multiple connected components, or else from a set of zero-dimensional OMs. Thus, conventional streams of digital audio in PCM format may be received as cyber forcing terms by an OM.

The geometry of the source and target OMs may not correspond initially. For example, a source forcing term ƒ_{c} may be a signal measured over a two-dimensional region, such as a cap of a spherical OM and it may be utilized according to methods of the present invention as provided below over the entirety of a flat disk-shaped OM. In order to reparameterize a source force ƒᵢ to be utilized on a target OM, a harmonic or conformal mapping procedure is utilized. Harmonic mappings have the important benefit of minimizing the Dirichlet energy amongst all possible reparameterizations. Conformal maps are also harmonic, but they furthermore preserve angles in the underlying geometry, which leads to the preservation of features of the sound field data which the geometry parameterizes.

In the case of a forcing term ƒ sampled over a source submanifold Mₛ^{sub} and reparameterized to fall upon a submanifold Mₜ^{sub} of a target manifold M₂ by a harmonic or conformal map h, such that, to each vertex of the source submanifold, a unique point on the target submanifold is assigned, then the value of a given ƒᵢ at a vertex v∈Mₜ^{sub} of the target manifold is given by

ƒ(v)=p(h⁻¹(v)) (28)

where p:Mₛ→ [symbol] is the SPF on the source manifold Mₛ; i.e., pₛ(h⁻¹(v)) denotes the value of the SPF on Mₛ^{sub} at the preimage of the vertex v of M₂^{sub} under the map h:Mₛ^{sub}→Mₜ^{sub}. If the preimage (h⁻¹(v)) does not lie at a vertex of Mₛ^{sub}, then the value of the SPF there is computed using barycentric coordinates as a weighted linear combination of the values of the SPF at the vertices of the simplex containing the preimage point.

Note that, in general, functions ƒᵢ may be defined over only part of the target OM Mₜ if the image of the map h is a strict submanifold (i.e., its complement in the total manifold of the OM is nonempty). In such cases, the forcing term ƒᵢ can be extended to an entire function by setting the values over the rest of the total manifold to zero, i.e.

$${\hat{f}}_{i} = \{ \begin{matrix}{f}_{i} ( υ ) , & υ ⊆ {h}_{i} ( {M}_{s}^{sub} ) \\ 0 & else\end{matrix} \qquad ( 29 )$$

where hᵢ is the coupling map of the i^{th} coupling. Other options include using a spatial smoothing function, such as a Gaussian, to smooth, or mollify, the values which lie at the boundary of where the forcing term is defined and its complement.

Note that in order for the forcing term to be obtained as in equation (28), the map h must be invertible, and thus injective (i.e., it sends each point in its domain to a unique point in its codomain). In practice this condition is easily fulfilled, but it excludes multiple or ‘winding’ coverings. If h fails to be injective at a vertex, then natural strategies exist for assigning a unique value at that vertex. For example, the value at a vertex where h is non-injective may be set to zero, or else set as the sum of the values of the function p over the fiber of the vertex v under the map h (i.e., the set of points in the preimage of h at v, {r∈Mₛ^{sub}|h(r)=v}). In the case that the coupling maps hᵢ for each of the forcing terms in a set of forcing terms ƒᵢ (cyber or physical) are all injective, the update equation for a target OM with underlying simplicial manifold Mₜ is:

$$\ddot{u} = - Δ u + {\sum }_{i ∈ I} {\hat{f}}_{i} \qquad ( 30 )$$

$$where$$

$${\hat{f}}_{i} ( υ ) = \{ \begin{matrix}{p}_{i} ( {h}^{- 1} ( υ ) ) & υ ∈ Im ( {h}_{i} ) = {h}_{i} ( {M}_{s , i}^{sub} ) \\ 0 , & else\end{matrix} ,$$

where Im(hᵢ) denotes the image of the map hᵢ, and M_{s,i}^{sub} denotes the submanifold of the i^{th} source manifold, M_{s,i}.

If the coupling maps are not injective, then a natural choice is to use a sum over the preimage of each vertex. Equation (30) then becomes

$$\ddot{u} = - Δ u + {\sum }_{i ∈ I} {\hat{f}}_{i}^{n - i} \qquad ( 31 )$$

$$where$$

$${\hat{f}}_{i}^{n - i} ( υ ) = \{ \begin{matrix}{\sum }_{w ∈ {h}_{i}^{- 1} ( υ )} {p}_{i} ( w ) , & υ ⊆ Im ( h ) = h ( {M}_{i , 1}^{sub} ) \\ 0 , & else\end{matrix}$$

and pᵢ denotes the SPF over the i^{th} source mesh, and ω∈hᵢ⁻¹ is a point in the fiber of the map hᵢ over the vertex v. Alternatively, options for dealing with the noninjectivity can be substituted for the sum in equation (31).

Note further that, if the domain over which a physical forcing term ƒₚ is sensed in the real world is a sensor array represented by a mesh M_{s,p} that is also a simplicial manifold, then the physical forcing term ƒₚ may be reparameterized over a target OM with underlying mesh M t using a harmonic or conformal map h:M_{s,p}→Mₜ. Such a mapping is trivial in the case of a conventional point-sensor such as a microphone measuring a single scalar value (acoustic pressure or velocity) over time at a point in space, as it corresponds simply to an assignment of the sensor location to a point on the target manifold. However, ƒₚ may, more generally, be sensed over a sensor array or sensor network, W, the spatial arrangement of the individual sensors of which is represented by a mesh. I.e., the forcing data coming from the sensor is, itself, represented by a function over a mesh that is a simplicial manifold and so mappable using the strategies described herein. The only difference between physical and cyber forces in this conception is that the evolutions of fields over meshes modeling sensor arrays inhabiting areas or volumes of physical space in which physical forces are being measured are not driven by discrete Laplacian operators and adaptively refined using a computer as in case of cyber OMs. Rather, the sensor data are understood to be measurements taken of analog media evolving according to Laplacian-driven dynamics due to independent physical processes. For example, in the case of a sensor array measuring acoustic pressure in a body of air, the acoustic pressure data as measured by each sensor at its location in physical space in time evolves according to an acoustic wave equation, as a result of natural acoustic and fluid dynamical processes.

### Reparameterization of Surfaces Via Harmonic and Conformal Maps

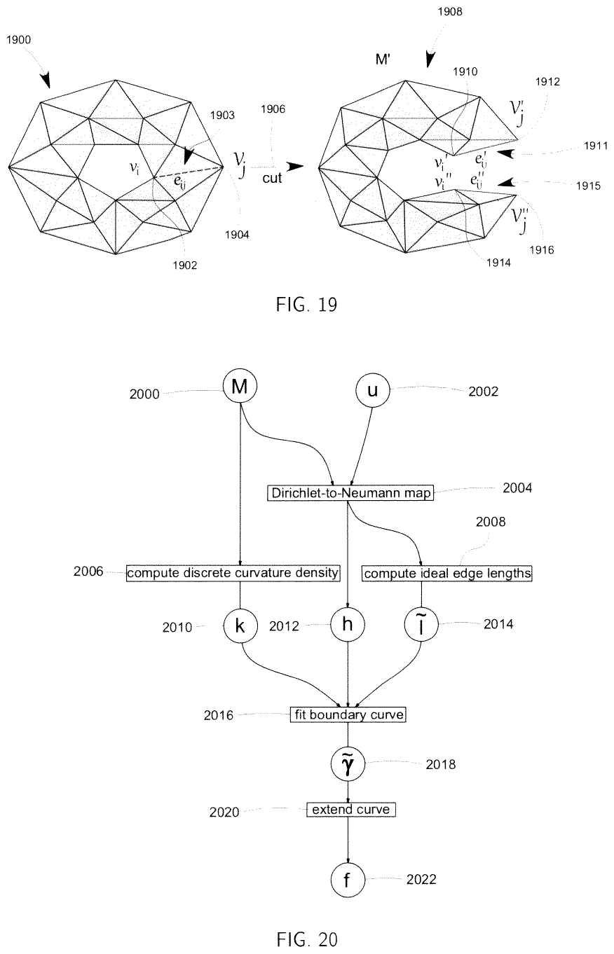

We now turn to the definition and computation of harmonic and conformal maps between simplicial surfaces. There are many equivalent formulations of conformal maps in the smooth setting, which however lead to inequivalent discrete formulations. Additionally, there are different algorithms existing which are optimized for discrete conformal maps between different kinds of discrete spaces, for example triangulations of spaces with different topology, such as the disk or sphere. Accordingly, as pertains to the present subject matter we first focus on a finite element-type definition of a discrete conformal map from a disk-like surface S. The definition faithfully captures the behavior of smooth conformal maps in the limit of refinement. Treatment of the case of surfaces of disk topology furthermore allows for methods applicable to surfaces of other topological character to be derived via manifold cutting methods; for example, an annulus (1900) that is cut along a radial edge (1903) between vertices (1902) and (1904) to form a a surface (1908) having a new edge (1911) between new vertices (1910) and (1912), and a new edge (1915) between new vertices (1914) and (1916) along the cut, and which is topologically a disk and so can be mapped using the disk-based methods, is shown in. FIG. 19). The case of mapping between surfaces of disk-topology illustrates the local behavior of the mapping that is independent of the global topology.

First, recall as stated above that for a simplicial surface S=(V, E, F), a solution to the discrete Laplace equation using the cotangent or simplicial Laplace operator, is a discrete harmonic function ϕ:V→ [symbol] . Equivalently, it is function which minimizes a discrete version of the Dirichlet energy (c.f. Konrad Polthier, Polyhedral.). In the smooth setting, the Dirichlet Energy of a map ƒ:M₁→M₂ between Riemannian manifolds is the functional

E_{D}(ƒ):=∫_{M}_{₁}|dƒ|²dV (32)

where dV is the volume measure on M₁. The function ƒ is harmonic if it is a critical point, i.e. a local minimum or maximum, of E_{D}. Given a discrete metric l:E→ [symbol] _{>0}, i.e. a set of positive edge weights satisfying the (strict) triangle inequality on S, a discrete version of equation (32) is given in terms of the cotangent edge weights,

$${w}_{ij} := \frac{1}{2} ( cot {θ}_{k}^{ij} + {cot}_{l}^{ij} ) ,$$

as

$${Ê}_{D} ( f ) : = {\sum }_{i j ∈ E} {w}_{i j} \vert {f}_{j} - {f}_{i} {\vert}^{2} \qquad ( 33 )$$

For a treatment of the relationship between the smooth and discrete Dirichlet energies (16) by (17), see [K. Crane, “Conformal geometry of simplicial surfaces”, in Proceedings of Symposia in Applied Mathematics, vol. 76, 2020, pp. 59-101], which is incorporated by reference.

Recall further that in the smooth setting, a function ƒ:M→ [symbol] , which may be written as ƒ=a+bi where a, b:M→ [symbol] are a pair of real-valued functions, is holomorphic if it satisfies the Cauchy-Riemann equations: df(JX)=idf(X), where X is a tangent vector, J denotes a quarter-turn on the surface, df(X) is the tangent vector to which X is mapped in the complex plane, and ι is the imaginary unit (which denotes a quarter-turn in the complex plane). An equivalent condition in order that ƒ be holomorphic is if a and b form a conjugate harmonic pair, i.e. are a pair of real harmonic functions with orthogonal gradients

Δa=0

Δb=0

∇b=J∇a

which, in the Euclidean case, corresponds to the set of equations

$$\frac{{\partial }^{2} a}{\partial {x}^{2}} + \frac{{\partial }^{2} a}{\partial {y}^{2}} = 0$$

$$\frac{{\partial }^{2} b}{\partial {x}^{2}} + \frac{{\partial }^{2} b}{\partial {y}^{2}} = 0$$

$$\frac{\partial a}{\partial x} = \frac{\partial b}{\partial y} and \frac{\partial b}{\partial x} = - \frac{\partial a}{\partial y} .$$

A holomorphic function ƒ is furthermore conformal if it is also an immersion, i.e. has nowhere vanishing derivative (it maps nonzero vectors to nonzero vectors, equivalently in the discrete case if the map is locally injective on the stars of vertices). Any conformal map ƒ is equivalently characterized by its associated conformal (scale) factor e^{u}:=|df(X)|/|X|. The function u:M→ [symbol] is referred to as the log conformal or just scale factor, and measures the change in length induced by the conformal map at each point on the surface; for example, if u is constant and of unit magnitude, then the map exhibits minimal area distortion [Springborn et al., 2008].

An efficient computational scheme for discrete conformal maps between disk-like domains which is furthermore consistent with the foregoing treatment is the boundary first flattening (BFF) algorithm. Input to the algorithm is a triangle mesh of disk topology that is equipped with a discrete metric (i.e., assignment of edge lengths satisfying the triangle inequality on each triangle), and optionally either scale factors or exterior angles (which must sum to 2π) at boundary vertices of the target domain. If no scale factors or exterior angles are specified, then the default behavior is to compute the parameterization which minimizes area distortion, which is obtained by setting scale factors along the boundary to zero, u|_{∂S}=0. We generally assume this latter condition unless stated otherwise; later, we describe a case in which a user or operator of the system provides the optional specified input data. Output of the algorithm is a flattening of the input mesh, i.e., a function ƒ:V→ [symbol] from the vertices of the mesh into the complex plane, which approximates a smooth conformal map with the given boundary data.

The basic sequence of steps taken by the algorithm is the following. First, the interior angles at the corners of each triangle of the mesh are computed. Next, discrete Gaussian and geodesic curvature densities are computed at interior and boundary vertices, respectively. Then, the cotangent matrix is formed using the computed angles, if it is not already available (for example, if the OM evolution is being computed in parallel by a number of CPs, such that no one CP stores the entire cotangent Laplace matrix of the underlying mesh). Next, the cotangent Laplace matrix is decomposed using a Cholesky factorization, i.e. as A=RR^{T}, in terms of block matrices corresponding to the interior and boundary vertex sets, in order to enable efficient computation of subsequent steps in the algorithm. Then, depending on whether scale factors or target exterior angles were given as input to the algorithm (where zero scale factors is the default case), the complementary boundary data for a conformal map is obtained using a Dirichlet-to-Neumann map or a Neumann-to-Dirichlet map, respectively, and the target edge lengths are computed using the scale factors. Next, the target boundary curve which best fits the conjugate boundary data is computed using a discrete Hilbert transform. Finally, the target boundary curve is extended over the interior of the domain, returning a conformal map ƒ:V→ [symbol] . We next go through these steps in more detail.

Computing a conformal flattening using the BFF algorithm involves as its primary computational routine solving Poisson-type equations for Dirichlet and Neumann-type boundary conditions. We can represent this in matrix form as follows. Let A denote the cotangent-Laplace matrix of the mesh, a,ϕ:M→ [symbol] be real-valued functions on the mesh, representing the function to be solved for and the forcing function, respectively, and g,h:∂M→ [symbol] be functions prescribing the values or normal derivatives of a along the boundary, respectively. Let |B| denote the set of boundary vertices; then the function a restricted to the boundary is g, a_{B}=g∈ [symbol] ^{|B|}. Thus, the Dirichlet-Poisson problem is Δa=ϕ on M, such that a=g on ∂M. Similarly, the Neumann-Poisson problem is Δa=on M, such that

$$\frac{\partial a}{\partial n} = h$$

on ∂M. The Neumann-Poisson problem is represented in block-matrix form as

$$[ \begin{matrix}{A}_{I I} & {A}_{I B} \\ {A}_{I B}^{T} & {A}_{B B}\end{matrix} ] [ \begin{matrix}{a}_{I} \\ {a}_{B}\end{matrix} ] = [ \begin{matrix}{ϕ}_{I} \\ {ϕ}_{B} - h\end{matrix} ] \qquad ( 34 )$$

where h∈ [symbol] ^{|B|} is the discrete Neumann boundary data, and the blocks map between: (II) interior vertices and interior vertices; (IB) boundary vertices and interior vertices; and (BB) boundary and boundary vertices; whereas, the Dirichlet-Poisson problem solution is then obtained by solving the first row: A_{II}a_{I}=ϕ_{I}−A_{IB}g.

An efficient implementation of BFF uses a Cholesky factorization, A=RR^{T}, of the cotangent Laplace matrix A, allowing for efficient solution of Dirichlet- and Neumann-type Poisson problems via backsolutions. Specifically, A can be factorized in its block form given in 34, as

$$[ \begin{matrix}{A}_{I I} & {A}_{I B} \\ {A}_{I B}^{T} & {A}_{B B}\end{matrix} ] = [ \begin{matrix}{R}_{I I} & 0 \\ {R}_{B I} & {R}_{B B}\end{matrix} ] [ \begin{matrix}{R}_{I I}^{T} & {R}_{B I}^{T} \\ 0 & {R}_{B B}^{T}\end{matrix} ] .$$

Then the upper left block gives the Cholesky factorization A_{II}=R_{II}R_{II}^{T} of the cotangent matrix of the interior vertices, which is involved in solving the Dirichlet-Poisson problem. The remaining blocks of A are given by the associated sums and products of the blocks of R and R^{T}.

A key part of the BFF algorithm is computing the complementary boundary data of a conjugate harmonic function for a conformal map. In the case where initial scale factors were given, this is done using a Dirichlet-to-Neumann Poincare-Steklov operator. Converting from the Dirichlet to Neumann boundary data of a Poisson problem with nonzero source term ϕ is achieved by computing

Λ_{ϕ}g:=ϕ_{B}−A_{IB}^{T}A_{II}⁻¹(ϕ_{I}−A_{IB}g)−A_{BB}g

which effectively solves the Dirichlet-Poisson equation, Ra_{I}=A_{IB}g (where aᵢ is as computed above, a_{I}=A_{II}⁻¹(ϕ_{I}−A_{IB}g)), and then subtracts the Laplacian of the Poisson solution at the boundary. The result is the Neumann data h:B→ [symbol] .

The Neumann boundary data, h, then makes it possible to compute the discrete curvature \tilde{k} of the target boundary curve, since the discrete boundary curvatures of the source and target domains are related by h=k−\tilde{k}. Recall that, at each boundary vertex, the discrete Geodesic curvature density is defined by kᵢ:=π−Σ_{ijk∈F}βᵢ^{jk}, which for a planar surface is equivalently the exterior angle at the vertex, i.e. the deviation of the vectors tangent to the edges meeting at the vertex from forming a straight line. At each interior vertex, in contrast, the discrete Gaussian curvature density measures the deviation of the surface from being flat at the vertex, i.e., of the difference between sum of the interior angles of triangles incident to the vertex and the quantity 2π, and is defined by Ωᵢ:=2π−Σ_{ijk∈F}βᵢ^{jk}. Note that this is an integrated quantity, thus it measures the curvature integrated over a small neighborhood around the vertex.

Now, let l* denote the edge lengths of the ideal target boundary curve, computed as lᵢⱼ*=e^{(u}^{ᵢ}^{+u}^{ⱼ}^{)/2l}^{ᵢⱼ}, where lᵢⱼ is the length of edge ij in the source domain. In order to obtain a closed target boundary curve in the plane while preserving the exterior angles \tilde{k}, the edge lengths l* must be minimally adjusted. BFF next constructs a polygon \tilde{γ}, with vertices \tilde{γ}ᵢ∈ [symbol] in the complex plane having the angles \tilde{k} as its exterior angles and having edge lengths that closely match l*. This is done by, first, computing the cumulative angles φₚ:=Σᵢ₌₁^{p-1}\tilde{k}ᵢ and target tangent vectors \tilde{T}ᵢⱼ:=(cos(φᵢ),sin(φ)). The optimal edge lengths \tilde{l} are then computed as \tilde{l}=l*−N⁻¹(\tilde{T}N⁻¹\tilde{T}^{T})⁻¹\tilde{T}l*. See (Shawney and Crane, BFF 2018) for a derivation of this formula. The final vertex positions \tilde{γ}ᵢ are then computed via the sums γᵢ:=Σᵢ₌₁^{p-1}\tilde{l}ᵢⱼ\tilde{T}ᵢⱼ.

The final step in the BFF algorithm is to interpolate the boundary curve obtained above, over the interior of the target domain. This is done by solving for the complementary boundary data of the conjugate harmonic functions, using the discrete Hilbert transform. As described in (Shawney and Crane, BFF 2018), for a disk-like domain, the operator mapping the tangential derivative of a harmonic function a to the normal derivative of its harmonic conjugate, b, is called the Hilbert transform, H. This provides boundary data for a holomorphic function, ƒ=a+bi. One then solves a Neumann boundary problem to obtain the harmonic function b that is conjugate to a.

More specifically, given a discrete harmonic function a:V→ [symbol] , its harmonic conjugate can be obtained as the function b:V→ [symbol] that minimizes the least-squares conformal energy, E_{c}, which measures the failure of a function to satisfy the Cauchy-Riemann equations (See Crane, Conformal Geometry of Simplicial Surfaces). The energy E_{c} can be expressed in terms of the Dirichlet energy E_{D} minus the area of the image of ƒ. This can be expressed in matrix form, as

$${E}_{C} ( a , b ) = [ {a}^{T} {b}^{T} ] [ \begin{matrix}A & U \\ {U}^{T} & A\end{matrix} ] [ \begin{matrix}a \\ b\end{matrix} ]$$

where A is the cotan-Laplace matrix, and U denotes the signed area of the boundary polygon:

$${a}^{T} U b : = \frac{1}{2} {\sum }_{i j ∈ \partial M} {a}_{j} {b}_{i} - {a}_{i} {b}_{j} \qquad ( 35 )$$

For a fixed harmonic function a, the conjugate function b can thus be obtained by minimizing E_{C}, equivalently to solving the Neumann-Laplace equation Ab=−U^{T}a. The minimizer is the solution to the discrete Laplace equation Ab=0 on S subject to the Neumann boundary data

$${h}_{i} = \frac{1}{2} ( {a}_{i + 1} - {a}_{i - 1} ) \qquad ( 36 )$$

where i−1, i, and i+1 are consecutive vertices along the boundary. Since the harmonic function a is determined by its boundary values, the resulting conformal map is parameterized by a real-valued function on ∂S and fixing Dirichlet or Neumann boundary conditions.

Algorithmically, interpolation of the boundary curve \tilde{γ} is achieved by the following. First, the real part of the boundary curve \tilde{γ} is extended harmonically over the domain, by solving R_{II}a_{I}=−A_{IB}Re(\tilde{γ}). Then, the Hilbert transform of a is computed to obtain complementary boundary data for each boundary vertex i∈B,

$${h}_{i} = \frac{1}{2} ( {a}_{i + 1} - {a}_{i - 1} ) .$$

Finally, the conjugate harmonic function b is solved for, as Ab=h, thus providing the real and imaginary parts of the complex function, a+ib. An overview of the sequence of steps taken in the BFF algorithm is shown in FIG. (20), wherein a mesh (2000) and optional scale factors (2002) are input to a Dirichlet-to-Neumann map (2004), which is used in step (2008) to compute the ideal edge lengths (2014) and from which is also obtained the boundary data (2012); wherein the input mesh (2000) is further used to compute the discrete curvature density (2006), the output (2010) of which is used in step (2016) along with the boundary data (2012) and ideal edge lengths (2014) to fit a boundary curve (2018), which is extended in step (2020) in order to obtain a final flattening (2022).

The BFF algorithm can be used for automatic parameterization and direct editing of surfaces. It can be used either to directly map between surfaces, or in a multi-step fashion to perform mapping to an intermediate uniform domain. For uniformization, BFF can either target a predefined triangulation of the uniform domain. Alternatively, it can be used to achieve uniformization via an iterated scheme, such that given as input an arbitrary mesh that is topologically a disk, a triangulation of the unit disk is output after a number of steps. As shown in [Crane and Sawhney], BFF can be used iteratively to target a uniform circular domain, by prescribing new target angles \tilde{k}ᵢ at each iteration. Specifically, at iteration n, we have

$${\overline{k}}_{i}^{n} = \frac{2 π {\tilde{{l}_{i}}}^{n - 1}}{{Σ}_{i ∈ B} {\tilde{l}}_{i}^{n - 1}}$$

where \tilde{l}ᵢ is the dual edge length at vertex i. The dual edge to a vertex is shown in FIG. ( ). A conformal flattening is then computed normally. The procedure is stabilized by averaging the current and previously-computed exterior angles,

$${\tilde{k}}_{i}^{n} = \frac{1}{2} ( {\tilde{k}}^{n} + {\tilde{k}}^{n - 1} ) .$$

The BFF algorithm guarantees local injectivity whenever (i) the target shape is convex; (ii) the discrete Laplacian exhibits a maximum principle, which is for example the case when the underlying mesh satisfies the Delaunay condition (the condition that the no vertex lies within the circumcircle of any other pair of vertices); and (iii) the adjusted edge lengths of the reparameterization are positive. In practice, for well-conditioned triangulations, these conditions are easily met.

Other algorithms may be used for discrete conformal mapping. For example, methods based on spectral conformal parameterization (SCP), discrete Ricci flow (DRF), conformal equivalence of triangle meshes (CETM), angle based flattening (ABF), and circle patterns (CP) may be used. Specifically, DRF may be used to target spherical or hyperbolic geometries; however, it may fail to be injective, in which case the strategies alluded to above, such as taking a sum or average, which are natural for defining the value of the forcing function at a target vertex where the map is not injective can be used.

In the case of harmonic mapping, a discrete map may be constructed by first setting the locations of boundary vertices, e.g. by projection onto the unit circle in the case of uniformization, or by automatic parameterization to a target shape, and then by either repeatedly applying the cotangent Laplacian until a satisfactory degree of convergence is reached, or else solving the associated linear system of equations using a fast solver. In such cases, as above with the discrete conformal maps, if the boundary data is not specified by the user, then by default the automatic parameterization may be performed by setting the Dirichlet scale factors to zero along the boundary. To see conceptually that repeated application Lu of the cotangent Laplacian L for a simplicial manifold M to a vector u representing a scalar field on M leads to a harmonic function, note that applying L drives u by diffusion, or in other words, performs a smoothing of u. Repeated application of L then results in a function that converges to a harmonic one, since in the limit its value at any point is the average of the sum of the values at its neighbors.

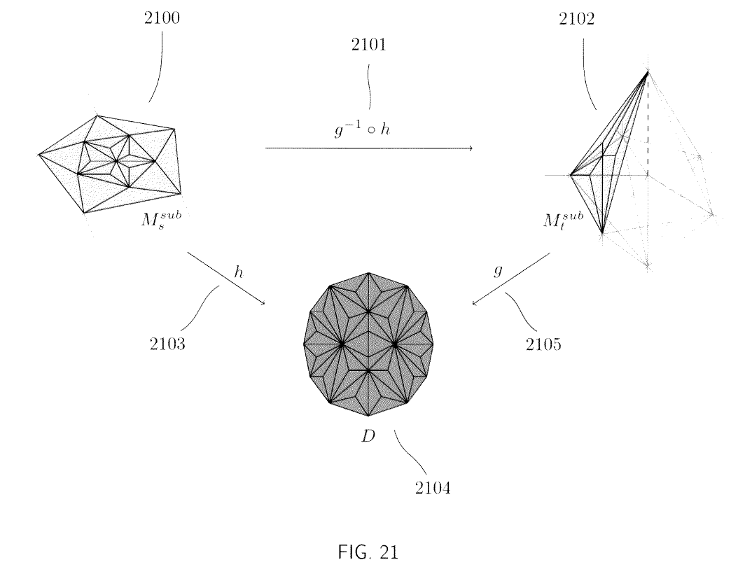

The Riemann mapping theorem in differential geometry states that any disk-shaped region U∈ [symbol] of the complex plane can be conformally mapped to the unit circular disk. As a corollary of this, any shape can be obtained via composition with an inverse Riemann map. This allows us to conformally map between disk-shaped surfaces by passing through the unit circular domain. A conformal map that is achieved by way of a uniform domain via composition with an inverse conformal map is shown in FIG. 21), wherein a disk-shaped simplicial submanifold (2100) is mapped via a map (2103) to triangulation of the uniform disk-shaped domain (2104); wherein a disk-shaped simplicial submanifold (2102) is mapped via a map (2105) to the uniform disk-shaped domain (2104); and wherein a map (2101) between the simplicial submanifolds (2100) and (2102) is obtained via a composition of the map (2103) with the inverse of the map (2105).

### Coupling

According to the present invention, a harmonic or conformal map can be used to define an interface between interacting OMs. According to the lexicography of the present invention, this interaction between OMs is called a coupling. Formally, a coupling between a pair of OMs (Qₛ, Qₜ) is a sextuplet [idₛ, Mₛ^{sub}, idₜ, Mₜ^{sub}, h, χ], where idₛ and idₜ are unique identifiers of the source and target OMs, respectively, Mₛ^{sub}⊆Mₛ is a simplicial submanifold of the simplicial manifold of the source OM Qₛ, Mₜ^{sub}⊆Mₜ is a simplicial submanifold of the simplicial manifold of the target OM Qₜ,

$$χ = \frac{{s}_{1}}{{s}_{2}}$$

and s₁, s₂ are the sample rates of the OMs Q₁ and Q₂, respectively, and h:Mₛ^{sub}→Mₜ^{sub} is a harmonic or conformal mapping from the submanifold Mₛ^{sub} to the submanifold Mₜ^{sub}. We refer to Mₛ and Mₜ as the total manifolds of the OMs Qₛ and Qₜ, in contrast to the submanifolds M₁^{sub} and M₂^{sub}.

More specifically, given a discrete total manifold M, a discrete submanifold is a discrete immersion ι:N→M into M of a discrete manifold N. A discrete immersion is a map ƒ:N→M that, when restricted to the star St(v) of each vertex v, is injective. The requirement that t be a discrete immersion rules out the possibility of the simplicial submanifold having vanishing angles, zero-length edges, and zero-area triangles. The map c may furthermore be limited to being an embedding, e:N→M, in order to exclude the cases of surfaces that have self-intersections when immersed in spaces that are low-dimensional.

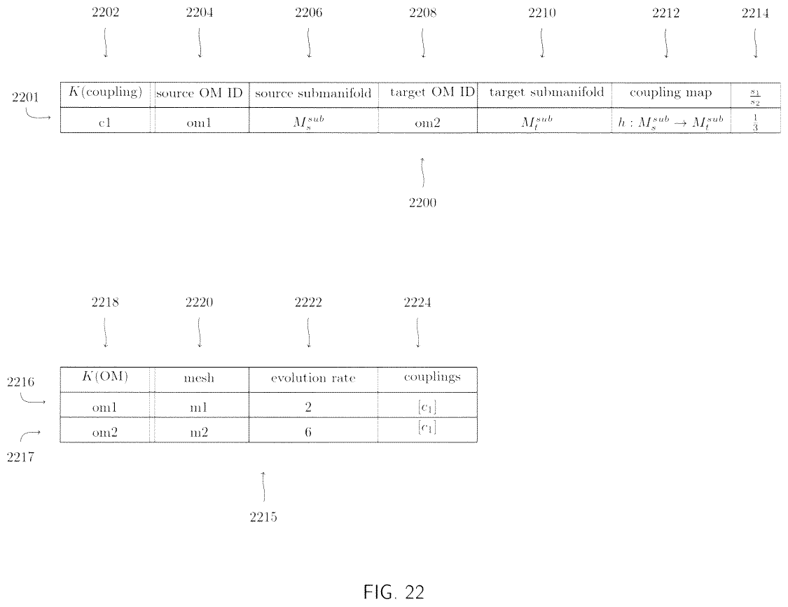

The data type above (i.e., the sextuplet) that encodes a coupling (2201) can be presented as a table (2200) as in FIG. 22), wherein the row (2201) representing the coupling contains the data of a unique identifier in the column (2202), the data of a source OM unique identifier in the column (2204), the data of a source submanifold in the column (2206), the data of a target OM unique identifier in the column (2208), the data of a target submanifold in the column (2210), the data of a coupling map in the column (2212), and the data of a ratio of evolution rates in in the column (2214). Also in FIG. 22), the data of the OMs that are the source OM (2216) and the target OM (2217) is presented in the table (2215). In each row of the table (2215), the entry in the column (2218) provides the ID of the OM, the entry in the column (2220) provides the mesh of the OM, the entry in the column (2222) provides the evolution rate of the OM, and the entry in the column (2224) provides the list of IDs of the couplings of the OM.

Note that the tables referred to above are conceptually global, in that the table of OMs contains all OMs in the system, and the table of couplings contains all couplings in the system. In particular, each coupling is specified fully in terms of both the source and target manifolds, and so, the full mesh data of both manifolds must be stored, either globally (e.g. directly in the coupling table), or else accessibly elsewhere and referred to.

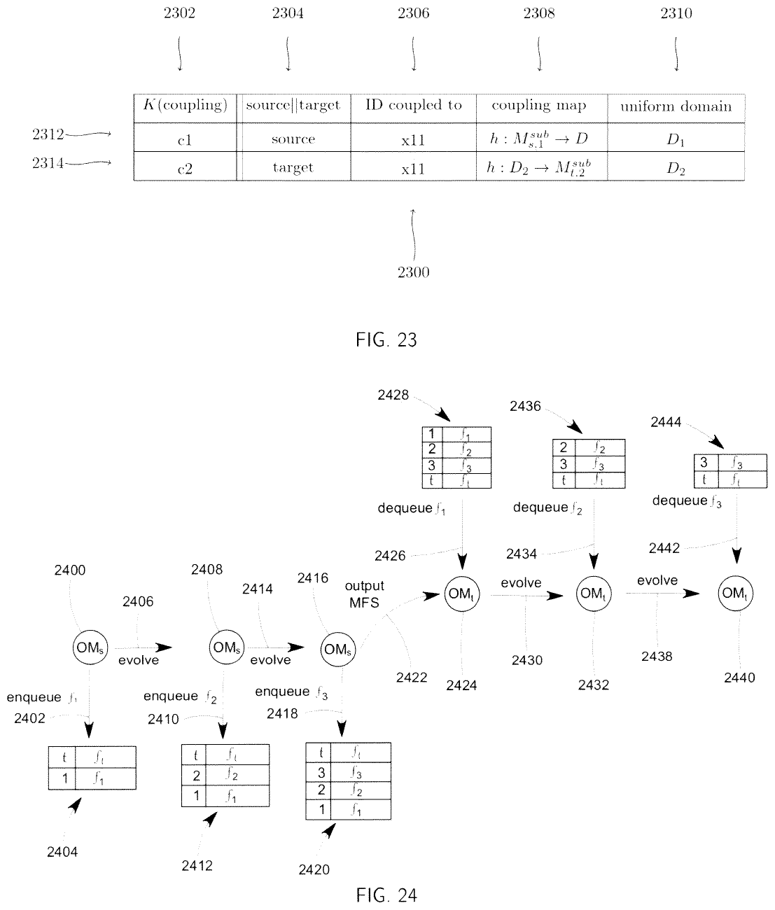

The data of the couplings of an OM may, alternatively, be stored as shown in FIG. 23), wherein a local coupling table (2300) stores the data of two couplings in the rows (2312) and (2314), and wherein for each row the data in the column (2302) provides the coupling unique identifier, the data in the column (2304) provides the data of whether the OM is a source or target of the coupling identified in the column (2302), the data in the column (2306) provides the identifier of the OM to which the local OM is coupled, the data in the column (2308) provides the coupling map of the coupling identified in the column (2302), and the data in the column (2310) provides the uniform domain of the coupling identified in the column (2302). In other words, the local coupling table of an OM allows for the coupling data to be split into two parts, one containing the data pertinent to the ‘transmitting’, or source OM; and the other containing the data pertaining to the ‘receiving’, or target OM. An OM using a local coupling table then stores locally the list of the IDs of all other OMs to and/or from whom it is transmitting and/or receiving on the network. Storage of the harmonic or conformal maps in two parts is facilitated using the uniform domain D. In the FIG. 23), the local OM is both a source and a target OM.

In practice, the ID may be associated to a device, referred to below as a computational platform (CP), responsible for computing the evolution of the OM and which are connected and communicate over a network. Alternatively, the ID of an OM may not correspond to any one CP, for example, if the computation of the evolution of the OM is distributed over multiple CPs. Or a single CP may be responsible for computing the evolution of many OMs. In such cases, the OM ID is understood to be ‘virtual’, and does not correspond in a one-to-one fashion to the device or devices responsible for evolving the OM. Routing of messages destined for CPs responsible for evolving different CPs can be achieved using standard methods for routing of packets through a distributed network, or general ad hoc (or mesh) network. For example, a distributed lookup table or distributed hash table (DHT) may be used to achieve the routing.

The coupling maps h₁, h₂ are specific to the two different couplings existing between the OMs. The uniform domains D₁, D₂ may or may not be topologically the same. One advantage of the local coupling table approach is that the memory required to store the data of any table is small when compared to the memory requirements of the global tables; this is made possible by using the uniform domain.

### Manifold Field Signal

A harmonic or conformal map can thus be used to reparameterize the sound field of a first OM over a second OM, such that a field of data in the first OM may be utilized to produce a perturbation, or forcing, in another OM. So far, the present specification has only described a method for combining single ‘slices’, or instantaneous snapshots, of sound fields. However, the method of the present invention can be extended to support the transmission and reception of signals that are parameterized both over the manifolds and by time indices. In other words, forcing signals received by OMs may also be of extended time, i.e. consist of many forcing terms that are ordered in a sequence. A manifold field signal (MFS) consists of a sequence of forcing terms defined over a simplicial manifold and sampled at a well-defined rate and at a well-defined numerical precision (bit depth). For example, the sample rate of a MFS measured from an OM may be the rate of the OM evolution, and the numerical precision may be single-precision or double-precision floating point format. MFS is an audio signal format for spatial audio, and as such generalizes PCM (pulse code modulation), the canonical time-domain format for one-dimensional digital audio, as the latter consists of a sequence of numerical samples at a fixed sample rate and bit depth, and so can be thought of as a stream of MFS at the 0-manifold that is a single point.

A MFS can be applied to an OM, to produce a time-varying forcing term, by application of each forcing term separately, as described above, and in order. In one example, each forcing term measured from an OM may be ‘pushed forward’ via a coupling map h. This can be done directly between two OMs, or via uniformization to a uniform domain, such as a circular disk D. (The latter is typically preferable because it enables local memory storage and for further reasons described below, relating to the consumption of computational resources.) Thus, in the preferred method, each forcing term θᵢ in a MFS is parameterized over a common uniform simplicial manifold, D. Thus, a MFS can be formed by: (1) sampling the SPF of an OM over a submanifold at each time step of its evolution, over an interval of time; and (2) mapping each measured field of data to the intermediary uniform domain. Thus, a MFS is, explicitly, a list of functions, [ƒₗ], (l=0, . . . , L), where each ƒₗ is a forcing term parameterized over a simplicial manifold, D. In the case of direct mapping between OMs, the ƒₗ are instead of the form ƒₗ:Mₛ^{sub}→ [symbol] or ƒₗ:Mₜ^{sub}→ [symbol] where Mₛ^{sub} and Mₜ^{sub} are the source and target submanifolds, respectively.

### MFS Buffers

In connection with any MFS transmitted between a pair of COMs are MFS buffers, or just buffers. Buffers are instrumental in the formation, transmission, reception, and application of MFS between COMs. They are populated by forcing terms, incrementally, during MFS formation, and are depleted of forcing terms, incrementally, during MFS application. The MFS itself is the data transmitted between the buffers. Formally, a buffer is an instance of the data type known as a queue. A queue is a first-in, first out (FIFO) data-type that can be modified using enqueue and dequeue operations. The enqueue operation pushes a datum onto the back of the queue, and the dequeue operation pops a datum from the front of the queue. A circular buffer of length n is a particular example of a queue, the elements of which can be indexed modulo n. In an implementation, a buffer may be of a fixed length L.

When a coupling is instantiated between a pair of COMs using buffers, then in addition to the information described in the section above titled Couplings, the coupling may be parameterized by a pair of positive integers, L^{s}_{B} and L^{t}_{B} representing the lengths of a pair of buffers associated to the coupling and referred to as the source and target buffers, respectively. A fixed-length queue of length L^{s}_{B} is then generated such that forcing terms measured from the source OM can be stored in it. Likewise, a queue of length L^{t}_{B} is generated such that forcing terms in it may be applied to the target OM. The queues may be initially empty.

Referring now to FIG. 24, an example of a procedure for the transmission of a MFS between a pair of COMs using source and target buffers is depicted, wherein manifold field data from a source OM at a state (2400) is enqueued via a map (2402) into a table (2404), and the OM then evolves by a time-step (2406), bringing it to a state (2408); manifold field data from the OM at the state (2408) is enqueued via a map (2410) into a table (2412), and the OM then evolves by a time-step (2414), bringing it to a state (2416); manifold field data from the OM at the state (2416) is enqueued via a map (2418) into a table (2420), at which point a MFS consisting of the data in the table (2420) is output, per the arrow (2422), and received as a MFS and stored in a table (2428) at a target OM at a state (2424); whereupon manifold field data from the table (2428) is dequeued via a map (2426) and applied to the OM at the state (2424); whereupon the OM at the state (2424) then evolves by a time-step (2430), bringing it to a state (2432); whereupon manifold field data from the table (2436) is dequeued via a map (2434) and applied to the OM at the state (2432); whereupon the OM at the state (2432) then evolves by a time-step (2438), bringing it to a state (2440); whereupon manifold field data from the table (2444) is dequeued via a map (2442) and applied to the OM at the state (2440), at which point no data of the MFS is left remaining to dequeue from the buffer at the target OM.

As a source OM evolves, if its SPF is measured in order to produce a forcing term, then the forcing term is enqueued and stored in the source buffer. Letting the buffers be initially empty at time t=0, and letting L^{s}_{B}=3=L^{t}_{B}, then if a forcing term ƒ₀ is measured on the source OM and enqueued into the source buffer, the source buffer now contains the data [θ₀]. At the next time step, t=1, the same process is repeated for the next forcing term, ƒ₁, and the source buffer contains the data [ƒ₀,ƒ₁]. At time t=2, the process is again repeated, and by the end of the enqueuing process, the source queue contains the data [ƒ₀, ƒ₁, ƒ₂], and so contains a sequence of forcing terms of length equal to L^{s}_{B}. This sequence is then used as the MFS, to be transmitted to the target OM. That is, the sequence of forcing terms in the queue is copied and used to form a MFS, which is transmitted to the target OM and enqueued in the target OM buffer. At the end of time-step t=2, the source queue is emptied. The reverse process is then carried out at the target OM. I.e., if at time t=3 the MFS has been received and enqueued into the target buffer, then the target buffer contains the data [θ₀, θ₁, ƒ₂]. The forcing term ƒ₀ is dequeued from the target buffer and applied as a forcing term to the target OM, and so the buffer contains the data [θ₀, ƒ₁]. The same process is then repeated at times t=4 and t=5. By t=6, the target buffer has then been emptied.

Buffers are thus used to control, i.e. to buffer, the formation, and application of MFS. However, an assumption in the above description is that the source and target OMs in the pair of COMs evolve at the same rate with respect to a global time, t. In practice, they may be evolved by different device which are connected over a network and which measure time according to different clocks.

Thus, in order to describe how MFS are received and processed by target OMs, it is necessary to provide a coherent model of time, and notion of time-step, not just for individual OMs but for a system of COMs. To do this, we introduce a Synchronous Reactive (SR) model that describes the ideal, or limiting case of temporal semantics for a system of COMs. Afterward, we introduce a more general model derived from the modeling framework known as Programming of Temporally-Integrated Distributed Embedded Systems (Ptides) model. The second, Ptides model allows for the ideal, SRmodel to be approximated deterministically in a real-world application by a given execution engine.

### Synchronous Reactive Systems

As already mentioned, synchrony is an important property of how acoustic media interact in the real world. It is essential for reliable communication. Another important property in the context of synchronous systems is reactivity. A reactive system is one which engages in ongoing dialogue with its environment. This is in contrast to so-called transformational systems, which merely process an input to produce an output. Acoustic media in the real world are examples of reactive systems, since they are in continuous interaction with their environment.

The reactions (also called update steps, or firings) of a reactive system may be event-triggered, i.e., may occur when inputs are received at the system's input ports. One example of an event-triggered reactive system is one which is driven by a clock signal, and so whose reactions occur at regularly spaced intervals of time.

Systems whose components engage in ongoing dialogue with their environments and evolve synchronously with one another are termed synchronous reactive (SR) systems. A SR system can be used as a model of a discrete system. A discrete system that is a composition of actors, i.e., of systems which receive and process inputs that are functions of finite sets, and produce outputs that are functions of finite sets. In a SR system, signals are presented to actors at ticks of a global clock, and the evolution of the system is, conceptually, a sequence of reactions occurring at discrete times, such that, at each such time, the reactions of all actors are simultaneous and instantaneous.

### SR Operational Semantics for a System of COMs

In a SR model of a system of COMs, each OM in the system evolves by a single time-step at each tick of a global clock. This update may be a ‘do nothing’ update, in which case the OM does nothing; or, it may be an evolution step, which consists of updating its SPF. The evolution rate of each OM is the rate at which it executes evolution steps, and is a multiple of a fundamental frequency, which is the reciprocal of the period of the global clock.

As described above, the SPF u is updated at each vertex according to the discrete IWE equation shown as in equation (13), i.e., first the acceleration term, or second time-derivative on the left hand side is computed, then the result is used to modify the velocity field (i.e., the field obtained by, at each vertex of the manifold, scaling the unit normal vector there by the value of the SPF), and then the velocity field is used to modify the scalar field that is the SPF, represented by the function u. Computing the acceleration term involves two procedures: computing the value of the Laplacian at each vertex; and applying any forcing terms to the SPF. If a single forcing term is received as input to the target OM of a coupling at a time t, then the forcing term is applied and the OM SPF evolves by a time-step according to the wave equation. If a MFS of length greater than one is received instead, then one forcing term is consumed from the signal at each subsequent evolution step of the OM using buffers, as described above, until no more forcing terms remain and the entire signal has been applied.

If the evolution rates, sₛ and sₜ of the source and target OMs are not equal, then the received MFS can be up- or down-sampled by the ratio,

$$χ = \frac{{s}_{t}}{{s}_{1}}$$

of the rates, before application to the target OM. This may be done in order that the length of time elapsed in applying the MFS to the target OM is equal in length to that which was elapsed in forming the MFS by measurement of the SPF over the source OM, and also such that the frequency spectrum of the signal is effectively, or approximately, preserved under the transformation. This can be done in a variety of ways, as described farther below in the section titled Transformations of MFS.

At each tick of the global clock, each OM which executes an evolution step furthermore transmits and receives a set (which could be empty) of MFS signals, to and from one or many of the other OMs or itself, to which it is coupled. The data of these streams are dequeued from and enqueued into one or many buffers. Each OM then dequeues one forcing term from each of the target buffers for which it is the target, and applies the forcing terms to its SPF. The OM then executes a single time-step, i.e. evolves by the wave equation, propagating sound on its surface by one ‘spatial step’. If it is the source OM of any couplings, it then enqueues a forcing term into the buffer corresponding to each said coupling. Then, for any buffer which is full, it copies and empties the buffer's contents, to form a MFS which is then transmitted to the associated target OM.

As previously mentioned, the SR model of a system of COMs is an idealization, since in the real world, the reactions of systems are not exactly synchronous (as clocks in the real world drift relative to each other) and instantaneous (as computation takes time). In the present invention, we use the SR model described above of a system of COMs to specify the correct (ideal) behavior of the system. A separate model is further specified for use in an implementation, which approximates, on a given execution engine, the above SR operational semantics. This second model will produce a physical realization that is faithful to the SR model if certain assumptions hold. It is derived from a more general modelling paradigm, known as Ptides.

### Programming of Temporally-Integrated Distributed Embedded Systems (PTIDES)

A modeling paradigm that generalizes SR and can be used to approximate the SR operational semantics of a system of COMs is Ptides (Programming of Temporally-Integrated Distributed Embedded Systems). We provide below a self-contained treatment of Ptides, drawing from [E. A. Lee, “The past, present and future of cyber-physical systems: a focus on models”, Sensors, vol. 15, pp. 4837-4869, 2015], which we incorporate by reference; see that reference for more detail.

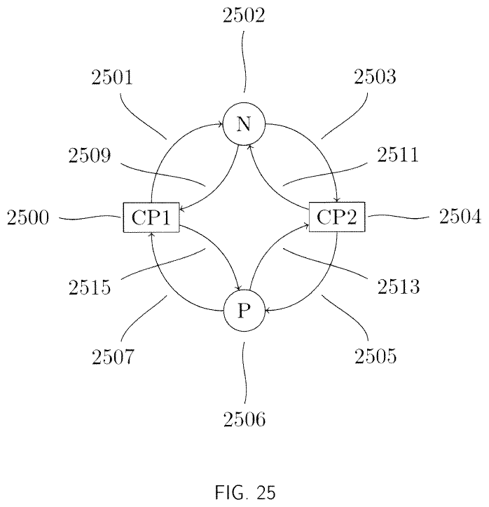

Ptides is a deterministic modelling paradigm for CPSs. Recall that a cyber-physical system (CPS) is an orchestration of computers, or electronic devices, and physical systems. Specifically, a CPS consists of a collection of computational platforms (CPs) that are connected to each other via transmitters and receivers—which propagate signals over a network fabric (NF)—and are connected to a physical plant (PP), which is an environment in the physical world, via sensors and actuators. An example of a CPS that includes two CPs (2500) and (2504) that are connected to a network fabric (2502) via transmitters and receivers per the arrows (2501), (2509), (2503), and (2511), and are connected to a physical plant P via sensors and actuators per the arrows (2505), (2507), (2513), and (2515), is shown in FIG. 25).

In a Ptides model, the timing of the firings (updates) of components in the system is controlled so that the evolution of the entire system is deterministic, under certain assumptions about the physical realization of the system. These assumptions are that: (1) clocks are synchronized with a known bound on the synchronization error; (2) every communication channel has a known bound on its latency; and (3) the time taken by any computation that may affect the physical world has a known bound. If these assumptions are valid for a given execution engine, then a Ptides model specifies an operational semantics (i.e., a behavior in time) that is deterministic. The second two assumptions are commonly met in real-time distributed software systems. In an example, the network latency bound in a given network may be taken as the maximal measured latency across all pairs of one-way trips, in a conservative estimate; else it may be taken as the average of those numbers, for a more liberal estimate. In order to bound the execution of software components, so as to satisfy constraint (3), specialized hardware can be used: in particular, so-called PRET (precise and repeatable timing) machines can be leveraged to more precisely bound the firing of software components at the hardware level. A clock synchronization protocol is used to satisfy constraint (1).

Time in a Ptides model is multiform—meaning that it runs at different rates, at different levels of the model—and it is superdense, meaning that at each level values of time are tuples (t, n), where t∈ [symbol] is referred to as the model time and n: [symbol] the microstep. The values of time are ordered lexicographically, i.e., (t₁,n₁)<(t₂,n₂)⇔t₁<t_{2∨}(t₁=t₂∧n₁<n₂); this allows events that are simultaneous according to the model time to nonetheless have a logical ordering given in terms of the microstep index. We next illustrate an example of a Ptides operational semantics for a simple CPS, shown in FIG. 2 (external view) and FIG. 3 (internal view).

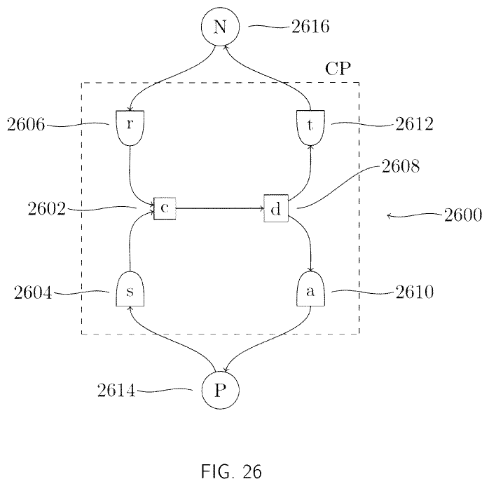

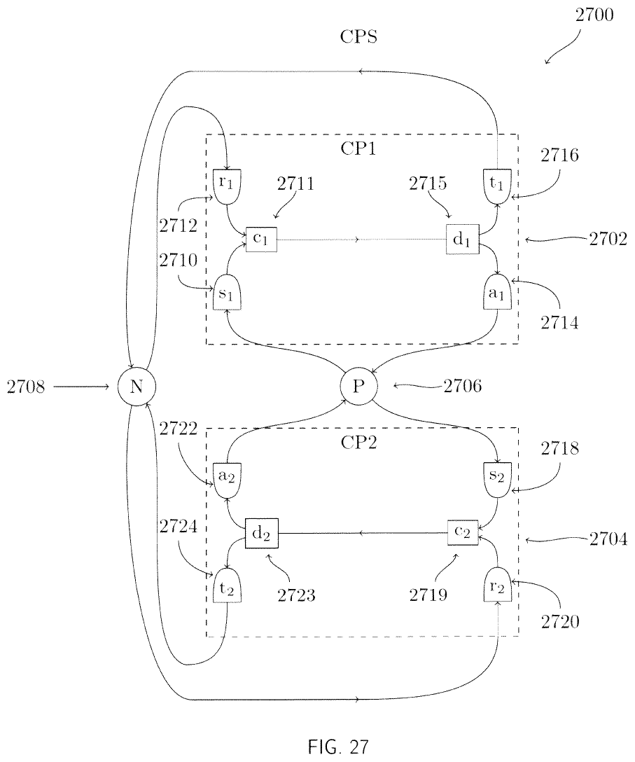

A central component of the methodology of a Ptides model is a ‘safe-to-process’ analysis, which is used to control the order of the execution and processing of discrete events throughout the system, by introducing controlled delays into the processing and communications chains of CPs. The delays are incorporated into the time-stamps of messages sent across the CPS network. Turning now to FIG. 26), a model of a CP is shown that includes a computer (2602), a sensor (2604), receiver (2606), transmitter (2612), and actuator (2610), and which is connected to a network fabric (2616) and a physical plant (2614). Note that there is additionally a delay unit (2608). Referring now to FIG. 27), we see a more detailed view of a CPS (2700) with two such CPs (2704) and (2702). As in FIG. 25), the sensors in FIG. 27 receive inputs from a physical plant (2706), the receivers from a network fabric, (2708), and the transmitters and actuators respectively output to the same. However, in a Ptides model, all messages and measurements taken are time-stamped, and the delay units are used to modify these time-stamps.

The basic form of the operational semantics of a Ptides model is as follows. Say that the sensor on CP1 takes a measurement. It time stamps it with the local platform time; denote this time by τ. The data of this measurement will be processed by the computation c₁ (which in the case of an OM, might be an evolution step). Assume that the computation c₁ produces an output (e.g., MFS) with the same timestamp, τ. What the box d₁ does is to increment the value of the time stamp by a constant, call it d₁ (by abuse of notation); it then transmits the output to CP2.

Now, on CP2, consider that there are two converging streams of input: one of measurements taken by the sensor s₂, and the other data received from CP1 by the receiver r₂. The events received at these two ports must be processed by the computation c₂ in time-stamp order. How can this be assured?

Assume that the bound on clock synchronization error is e and the bound on network communication latency is d. Then c₂ can safely process an event with time stamp t once the local platform clock of c₂ has reached or exceeded the time t+d+e. To see that this ensures a well-ordered execution of events, suppose that the output from CP1 was time stamped τ+d₁<t. Then (assuming the bound on network latency is accurate) this event will be received on CP2 before time τ+d₁+d<t+d, as measured by the clock on CP [symbol] . While the local platform clock may drift, their error is supposed bounded by e. Thus, the message from CP1 will be received before time τ+d₁+d+e<t+d+e on CP2. If no message has been received by time t+d+e, then the event with timestamp t is safe to process.

Once the computation c₂ has executed, it produces an event with time stamp t, but local platform time has already exceeded t by at least d+e. Thus, the logical delay d₂ modifies the time stamp to be t+d₂, where d₂>d+e, before delivering the output to either the transmitter or actuator port. However, while it is necessary (assuming the bounds d and e hold) for d₂>d+e, it may not be sufficient if the computation c₂ takes a long time to execute, where by sufficient we mean that the output event is delivered prior to the time given by the time stamp. In order to ensure this, it is necessary to bound the execution of the computation c₂.

Nonetheless, while the safe-to-process protocol does not guarantee that events are processed (i.e., actuated or transmitted) prior to the values of time by which they are stamped, it does guarantee that events are processed in the correct order. Thus, assuming that the bounds on clock synchronization error and network latency hold, the execution of discrete events in the system is deterministic. In order to ensure that events are delivered on time, it is furthermore necessary to bound the execution of software components. This can be done more precisely if there is support for timing built in to the hardware, as there is with PRET machines. The design of PRET machines integrates certain basic principles, such as: (interleaved threading?, ?, etc.).

It should be noted that, in a Ptides model, it is not strictly necessary for a computation to wait to process an event that has been received at an input port until the time t+d+e, as described above; the event can be processed prior to this time, however doing so will not ensure that events are processed in time-stamp order (even assuming the bounds on network latency and clock synchronization error are correct). Deterministic evolution may be more or less important depending on the application type. For example, in an audio application consisting of a number of participants who both speak and listen and in which it is imperative that the order of speaking should be known, the deterministic semantics may be useful; conversely, in a streaming situation where the precise order of events does not matter, then it may be turned off. We discuss another example where deterministic evolution may or may not be appropriate, depending on network latency, pertaining to parallelization, farther below.

### Ptides Model of a System of COMs

In a Ptides model of a system of COMs, each CP waits a prescribed amount of time before processing an update, using the safe-to-process analysis described above. This may be used, in the case of distributed and parallel computation of OM evolution, as well as in the transmission of MFS between COMs. In the first case, the data being exchanged between CPs pertains to the state of bounding vertices that lie in the regions of overlap between sections of a mesh underlying one OM, the evolution of which is being computed in parallel. In the second case, the data being transmitted is a sequence of forcing terms encoded as a MFS and transmitted between the COMs. Typically, the rate of transmission will be lesser in the second case, since MFS can be buffered so that the forcing data is transmitted in a batched fashion.

A set of CPs executing the evolution of an OM in a distributed manner and in parallel can execute their coordinated updates using the safe-to-process protocol according to the present invention in order to ensure a deterministic evolution of the OM. This will typically work well on a local area network (LAN) where network delay is low, if processing at audio rate is desired. If a high rate of evolution is required but the CPs are separated by a larger network latency, then the deterministic evolution protocol may be turned off to speed-up evolution of the OM.

### Clock Synchronization

In order to satisfy the first of the assumptions listed above for a Ptides model, a precision time protocol (PTP) is used to synchronize clocks on the network. Specifically, the best master clock (BMC) algorithm is used to perform a distributed selection of the best clock amongst a number of candidate clocks on a network segment, based on criteria such as user-defined priority, and clock quality, which is measured in terms of clock variance and accuracy. A grandmaster clock is elected and used to determine the time base for the entire network, and so-called master clocks are made subsidiary to it, but are also used to determine the time base for other clocks, which are further subsidiary to them on each network segment, in a clock hierarchy. A synchronization procedure is then used to synchronize all clocks on the network to the grandmaster clock. We incorporate by reference [J. Edison and K. Lee, “IEEE 1588 Standard for a Precision Clock Synchronization Protocol for Networked Measurement and Control Systems”, in [symbol] nd ISA/IEEE Sensors for Industry Conference, 2002, pp. 98-105]; see there for specifics as to how clock priority and quality is determined in the standard, as well as the specific names of message types and which ports they may be broadcast on.

Clock election takes place as follows. At startup, each clock device listens for a pre-defined period of time. Any clock may additionally be in a ‘primary’ state at initialization. Each clock that is in a primary state sends, at a pre-defined period, periodic sync messages to all other clocks to which it is connected. Any clock in a ‘primary’ state may also receive sync messages from other clocks claiming that they are ‘primary’; it calls them ‘foreign masters’. Each clock in a ‘primary’ state and receiving clock sync messages from other clocks in a ‘primary’ state then performs a comparison of the other clocks using a hierarchical selection process, selects the highest quality one among them, and compares that clock to itself; it thus determines whether it should remain a primary clock or switch into a subsidiary clock state relative to one of the foreign masters. Similarly, each subsidiary clock receiving sync messages uses the same BMC algorithm to determine whether it should switch to a primary state, in which case it begins broadcasting sync messages.

Following the IEEE 1588 standard, comparison of different clocks is performed on the basis of a hierarchy of factors that affect their quality. Specifically, IEEE 1588 standardizes the following list of factors: (1) Priority 1; (2) Class; (3) Accuracy; (4) Variance; (5); Priority 2; (6) Unique Identifier. See the reference incorporated above on the IEEE 1588 standard for more information about how clocks are compared.

For synchronization, the BMC algorithm is used. Each subsidiary clock synchronizes to its primary clock using a synchronization protocol that involves the exchange of Sync, Delay_Req, Follow_Up, and Delay_Resp messages exchanged between itself and the primary clock. This is done in order for each subsidiary clock to determine the offset between itself and the primary clock. Denote the physical time by t, and the time as measured by a given subsidiary clock at time t as s(t). The offset is then o(t)=s(t)−p(t), where p(t) is the time as measured by the primary clock at t. It is assumed that the offset, o, is essentially constant over a small-enough time interval. The synchronization procedure can then be carried out periodically, in order to update an estimate, denoted õ, of the offset value.

More specifically, at the first step in the BMCA, the primary clock periodically broadcasts its current time, tᵢ, to all clocks to which it is connected, in a Sync message. Depending on its network hardware, the primary clock may be able to present an accurate time-stamp of its current time along with the sync message; otherwise it subsequently sends a follow-up message containing the time t₁ at which the Sync message was transmitted. Assume that the time t₁ is included in the Sync message. The subsidiary clock thus receives the time t₁. Assume that it receives this at a time t′₁. It then has access to an estimate of the network delay from the primary to it; denoting this dₚₛ, we have that dₚₛ=t′₁−t₁. It next proceeds to determine the network delay, dₛₚ, from itself to the primary. It does this by sending a Delay_Req message to the primary, timestamped with the time t₂ of sending. The time at which the primary clock receives this message is denoted as t′₂. The primary clock responds to the Delay_Req message with a Delay_Resp message, in which it includes the time t′₂. Then the estimated delay from subsidiary to primary is dₛₚ=t′₂−t₂. If dₛₚ=dₚₛ, then network delay is equivalent in both directions.

The set of timestamp values can be organized into the following set of equations:

t′₁−t₁=õ+dₚₛ

t′₂−t₂=õ+dₛₚ

Assuming that the network delay is equivalent in both directions, we thus have that the offset õ is equal to the following

õ=(t′₁−t₁−t′₂+t₂)/2

The subsidiary clock thus has an estimate of the clock synchronization error between itself and the primary clock, and it can use this information to adjust timestamps attached to messages sent over the network, as described in the Ptides protocol for a system of COMs.

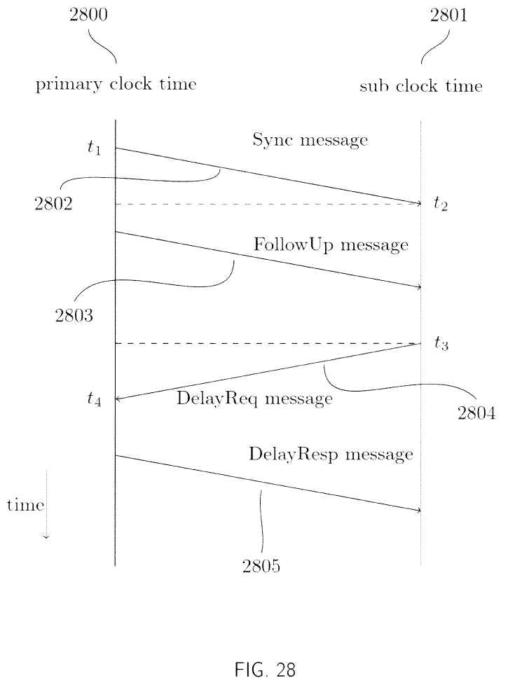

The BMC algorithm is depicted in FIG. 28), wherein in order to synchronize a primary clock (2800) with a subsidiary clock (2801), a Sync message (2802) is sent from the primary clock at a time t₁ to the subsidiary clock and is received by the latter at a time t₂; the primary clock sends a FollowUp message (2803) (if necessary); the subsidiary clock sends a DelayReq message (2804) at a time t₃, which is received by the primary clock at a time t₄, and finally the primary clock sends a DelayResp message (2805).

Note that the use of clock synchronization, beyond enabling the application of the safe-to-process protocol, makes it possible to precisely compare the evolution rates of OMs being evolved on different CPs. Thus, the evolution rate of an OM, as represented by a number (e.g., an integer), is given precise meaning, in relation to the global, or grandmaster, clock period.

### Parallelization

Numerical computation of the action of the L-B operator using the representation based on the cotangent formula lends itself to parallelization, because at each vertex in a mesh, the value of the L-B operator of the SPF defined at that vertex depends only on the value of the SPF at the vertex and at all neighboring vertices at the current time t. Thus, computation can be distributed by splitting the computational domain into two or more sections which cover the domain and which overlap at prescribed areas. If a different computer is assigned to process each section, then at time t those computers which are processing sections that overlap share data associated to the mesh elements at the boundaries of the overlapping sections, as described below. We refer to this as a patchwork type composition, since the domain is decomposed into two or more ‘patches’. (This parallels the case in the smooth setting of Riemannian geometry, where a topology on a manifold is traditionally defined in terms of a frame of open sets, which are equipped with local metrics and whose overlaps are described by an atlas for the manifold.)

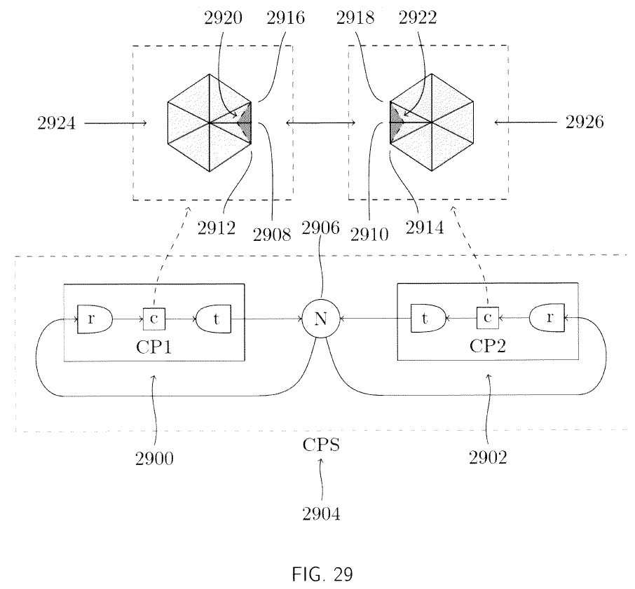

An example case of a CPS (2904) consisting of two CPs (2900) and (2902) connected by a network fabric (2906), as shown in FIG. 29). Evolution of a mesh according to the IWE may be computed by the two CPs, as follows. Each CP is assigned a section of a mesh to be computed in parallel. The CP (2900) is assigned the mesh section (2924) and the CP (2902) is assigned the mesh section (2926). The region of overlap (2920) and (2922) of the two sections includes the vertices (2908), (2910), (2912), (2914), (2916), and (2918), as shown, of which the vertices (2908) and (2910) are identified, the vertices (2912) and (2914) are identified, and the vertices (2916) and (2918) are identified. At each timestep, the CPs perform the following sequence of steps. First, the mesh data associated to the star and all neighboring vertices of each vertex in the region of overlap is shared between the corresponding CPs. That is, if vertex vₛ is shared between CPs 1 and 2, then CPs 1 and 2 share exchange messages so that each CP knows the data necessary to compute the cotangent formula at vₛ. The values of the SPF at the vertices surrounding vertex vₛ, as well as the interior angles and the lengths of edges incident to vₛ are shared. The SPF is then updated according to the IWE as per usual. (Alternatively, the information pertaining to the shared vertex may be transmitted to just one of the two CPs, which may compute the action and then share the result with the other CP, as needed.) Each CP can thus compute the action of the L-B operator over each vertex of the section of the mesh assigned to it, including at shared vertices. The field of SPF values thus determined over any of the regions of overlap and interior regions in the sections computed by the separate CPs can then be collated and used for different purposes, such as to generate a MFS over the entire OM. More abstractly, distributing the computation and mesh data allows for the dynamics of the mesh and the data it parameterizes to be ‘virtualized’ over a number of CPs.

The parallelization scheme described above may be used in conjunction with absorbing boundaries to provide a method for graceful failure and recovery of signals in a distributed evolution of an OM. Specifically, we use ABCs to facilitate the local computation of acoustic wave propagation in a way that provides robustness to sudden losses in the connectivity, or of messages passed, between computational platforms or components that are carrying out their realization in a distributed system. By way of an example, consider a spherical OM, the computation of whose evolution is distributed across two CPs and performed in parallel. Suppose that the sphere is decomposed into two topologically disk-shaped patches, which overlap along a bounding curve, and each of the disk-shaped patches is allocated to a different one of the CPs. Now, if an impulse is imparted somewhere on the sphere, say at the center of one of the disks, then waves will propagate radially out from the epicenter of the impulse. After some interval of time, they will reach the boundary of the two patches. Meanwhile, the two computers co-evolving their disk-shaped patches covering the sphere are periodically exchanging messages. But what happens if there is an unexpected interruption in the communication? E.g., what happens if computer A stops sending the star and boundary vertex data pertaining to the vertices of its disk to computer B? One possibility is that computer B uses the last set of values it received from A. Another possibility is that computer B sets the boundary values to fixed values, such as 0. However, either of these strategies induces a sudden change to the topology of the space being computed; it has introduced a boundary. Consequently, waves will be reflected from the new boundary back into the interior of B's domain.

However, the present invention takes a more graceful approach to such types of failure: if any computer A involved in executing a parallelized OM evolution drops out, then any other computer B to which computer A was sending boundary simplex data imposes an absorbing boundary condition at the now-severed connection. The result is, approximately, that waves are absorbed and not reflected back into the manifold domain. Therefore, any information contained in the absorbed signal will be lost, but will not contaminate successive transmissions should the computers reconnect at a later point. We refer to this as graceful failure and partial signal recovery.

### Transformations of MFS

In order to improve the scheduleability of a system of COMs on a real-world execution engine (CPS), or to preserve the ratios of the rates of evolution of different OMs, between which sound is flowing via one or more MFS, MFS may be transformed. In particular, they may be upsampled or downsampled. This can be achieved by interpolation of the vertex-signals (i.e., the sequences of SPF values over time at each vertex, considered separately, in the image, or target domain, of a MFS), or of the entire MFS at once. The latter can be achieved by interpolating the coefficients of the spectral representation of the forcing terms in the MFS. In both cases, a variety of interpolation schemes may be used, such as linear, quadratic, and sinc interpolation.

In the case of interpolation of a discrete signal ƒ[n] that is non-spatial, i.e. of a scalar-valued time-varying function, ideal interpolation is sine interpolation, which is given by the formula

$${f}^{′} ( t ) = {\sum }_{n = - ∞}^{∞} f [ n ] sin c ( \frac{t - n T}{T} ) , \qquad ( 37 )$$

where T is the period of the discrete input signal ƒ,

$$sin c ( x ) = \frac{sin ( π x )}{π x} ,$$

and ƒ′(t) is the output continuous signal, which may be sampled at any finite number of points. Likewise, the upper and lower bounds of the summation may be taken to be any finite cardinal. Thus, in the case of a MFS that is transmitted from a source OM evolving at a rate

$${r}_{1} = \frac{1}{{T}_{1}} ,$$

and received by a target OM which is evolving at a rate

$${r}_{2} = \frac{1}{{T}_{2}} ,$$

the interpolation formula 37 becomes

$${f}^{′} ( m {T}_{2} ) = {Σ}_{n = - ∞}^{∞} f [ n ] sin c ( \frac{m {T}_{2} - n {T}_{1}}{{T}_{1}} ) .$$

This process is then repeated for each of the signals obtained by restricting the MFS to a vertex in the domain of the associated coupling map (if transformation of the MFS is performed before mapping by the coupling map), or else which is in the image of the coupling map (if transformation is performed after pushing forward the MFS through the coupling map).

The MFS can also be interpolated using spectral coefficient. This can be done at different stages of the transfer of the MFS from the source manifold, Mₛ, to the target manifold, M₂: it can be done immediately upon formation of the MFS at the source OM, before harmonic or conformal mapping and transmission; or else it can be done over the intermediary uniform domain, D, if the coupling map passes through there;

or else it can be done after harmonic or conformal mapping and reception at the target OM. In the first and last cases, the eigenspectrum of the L-B operator for the source or target manifold, respectively, is used; whereas, in the middle case, either the eigenspectrum of the L-B operator for the particular discretization of the uniform domain D is used, or a continuous analytic representation of an eigenbasis for the domain can be used if one is known, since the former converges to it in the limit of refinement. We next consider each of these cases in turn.

Let L_{M}∈ [symbol] ^{|V|×|V|} be the cotan-Laplace matrix for a source OM with underlying simplicial surface M having vertex-set V, and let s=[ƒ_{τ}], τ=0, 1, . . . , N be a MFS of length N represented over M. Then the sequence s can be represented in the manifold spectral domain by decomposition of each forcing term in the MFS onto the manifold spectral basis provided by the eigenfunctions of L, as shown in 17. Thus, the signal s can equivalently be represented as a sequence of lists of spectral coefficients, s′[t]=\hat{ƒ}ₜ (where each \hat{ƒ}ₜ is of length |V|, \hat{ƒ}ₜ∈ [symbol] ^{|V|}). Then the signal of spectral coefficients at a vertex i is given by s′ᵥ_{ᵢ}=[\hat{ƒ}ₜ(i)], t=1, . . . , N. The sequence s′ᵥ_{ᵢ} can be interpolated as described above, e.g. linearly, quadratically, or ideally using sinc interpolation.

One benefit of using the spectral representations of the forcing terms in MFS, rather than interpolating per-vertex, is that it can allow for the sparsity of a signal sampled from an OM to be leveraged. For example, it may happen that the signal propagating on the source OM and sampled to form the MFS is a pure (manifold) sinusoidal signal, i.e. is non-zero at a single frequency in its spectral representation. Then only a single ‘per-frequency’ signal is required to be interpolated, in order to obtain an output MFS, at the desired sample rate, that is defined over the entire spatial (manifold) domain.

The same process as described above may, alternatively, be carried out after the initial MFS has been pushed forward through the associated coupling map. If the coupling map c:M₁→M₂ passes through a uniform domain, i.e., c=g⁻¹∘h, where h:M₁→D and g:M₂→D for D a uniform domain, then the process is identical to as described above, except that the matrix L is now replaced by the cotan-Laplace matrix for the uniform domain, L_{D}. However, since harmonic bases for uniform domains such as the smooth disk or sphere are typically known, they may simply be used instead as the spectral bases. If the map c does not pass through a uniform domain, then the interpolation process may still be carried out after mapping through c, and the matrix L_{M}_{₁} will be replaced by the cotan-Laplace matrix L_{M}_{₂} for the manifold M₂. This flexibility of where the interpolation may be processed means that, in actual execution of a system of COMs by a CPS, interpolation may be carried out at a CP that is evolving an OM which is the source OM of a coupling, the target OM of a coupling, or else which acts as an intermediary, processing a coupling between OMs that are being evolved by two other CPs.

Interpolation according to the interpolation formula 37 can also be computed in different ways. In particular, rather than computing the convolution as defined there directly, it may be computed as a composition of a zero-padding operation and a low-pass filtering operation (in the case of up-sampling), or a decimiation and low-pass filtering (in the case of down-sampling). In general, many known signal processing schemes should have analogues when it comes to MFS, with the unique added ingredient being that the ‘audio signal’ is now not a sequence of scalar values, but rather a sequence of scalar fields that are parameterized over a (simplicial) manifold, i.e., a manifold audio signal.

### Mesh Generation

### User Defined

A mesh in the present invention is a data structure in the shape of a simplicial manifold, which contains numerical data such as the SPF and the discrete metric. As will become clearer shortly, a mesh can also be thought of as a database, in which case the simplicial manifold of the mesh can be thought of as the database schema.

The underlying schema (i.e., the simplicial manifold) of a mesh may be generated in different ways. The first way is simply if it is given by fiat, as input to the system. Meshes are, in particular, ubiquitous in fields such as geometry processing and computer graphics, and so any mesh coming from such domain which is furthermore a simplicial manifold may be turned into an OM simply by evolving a function defined upon it as described in detail above.

Meshes may also be generated by a system user or operator, in a manual or ad hoc manner and as aided by a computer graphical interface. This is done by composing in sequence one or many elementary operations on meshes and on mesh schema, such as projections, unions, and joins. These operations correspond to projections, unions, and joins of the tables corresponding to the mesh. As described in [D. I. Spivak, “Simplicial Databases”, arXiv:0904.2012v1, 2009], which is incorporated by reference, a simplicial database is a general kind of database in which the schema of the database are simplicial complexes (more precisely, simplicial sets), and the data in the database are defined by sheaves over the schema.—In the present invention, there is the further requirement that the schema be simplicial complexes that satisfy the condition of being manifold. As described in those references, a schema in a simplicial database can equivalently be seen as a set of tables, each corresponding to a simplex in the schema, that are connected together via foreign key mappings, and whose relationships describe the precise set of connections between the different simplices in the schema. The data in these tables is then assigned to the schema using a sheaf, which assigns to each simplex a set, and to each face relation between simplices a restriction map, such that the integrity of data is respected. Using the language of Spivak, the data of a sheaf is stored as records in the tables corresponding to the different simplices. The data of an entire schema can be furthermore compiled into a single, global table, as described in the references.

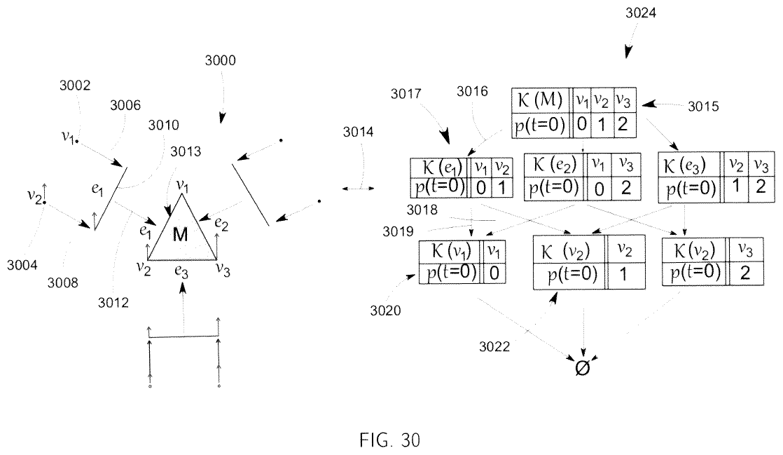

In FIG. 30), a schema (3000) and database (3024) are shown. In the figure, the vertices (3002) and (3004) include via the maps (3006) and (3008) into the edge (3010), which includes via the map (3012) into the triangle (3013). The precise structure of the inclusions between simplices corresponds, per the bidirectional arrow (3014), to the set of foreign key mappings in the database (3024), wherein the table (3015) restricts per the arrow (3016) to the table (3017), and the table (3017) restricts per the arrows (3018) and (3019) to the tables (3020) and (3022).

As described in [D. I. Spivak, “Table Manipulation in Simplicial Databases”, arXiv:1003.2682, 2010], which is also incorporated by reference, schema in a simplicial database naturally lend themselves to visualization and can be directly manipulated using a graphical interface. In that reference, the simplices of a schema are referred to as tiles, and a system for manipulation of the tables corresponding to tiles, and to schema themselves, is described which uses a graphical interface in order to allow a user to perform database queries like joins, projections, and unions by issuing commands via the interface.

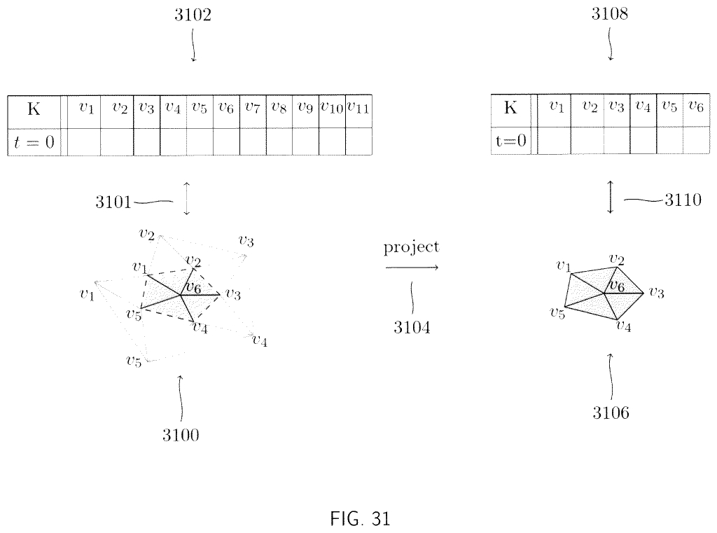

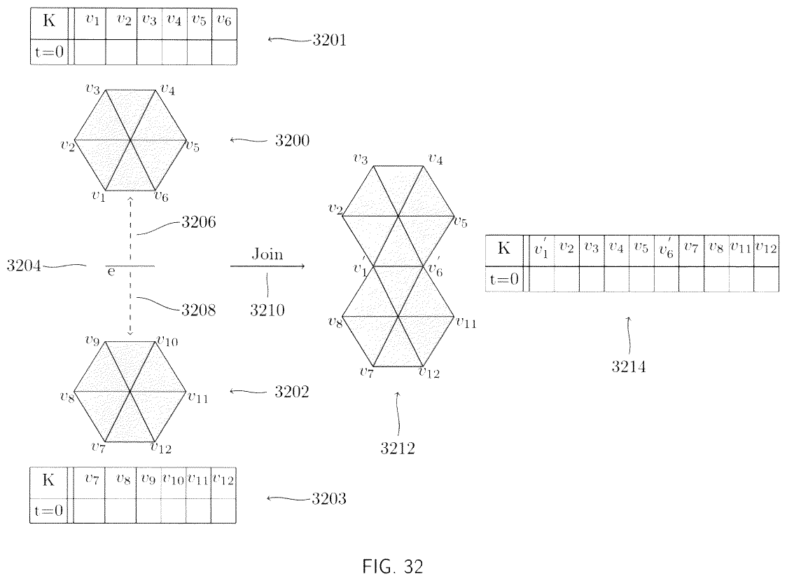

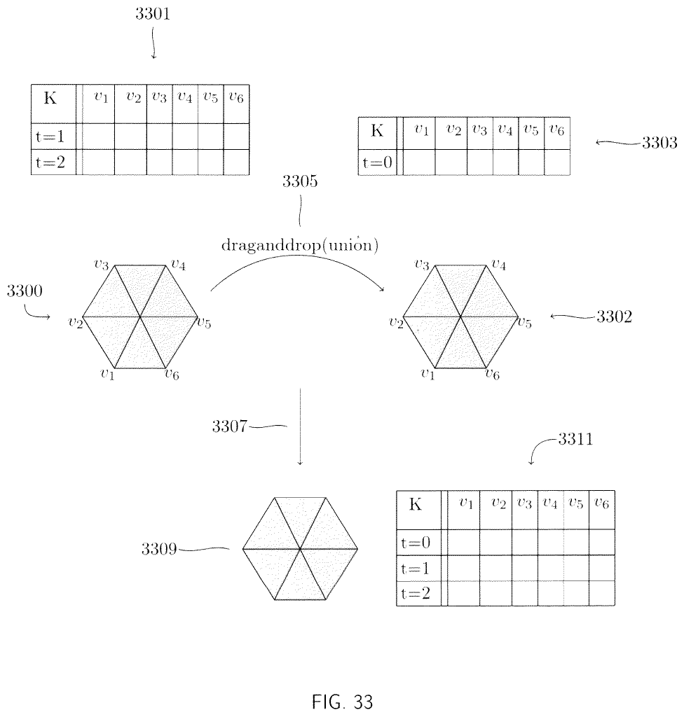

As described above, a mesh in the present invention is a simplicial manifold along with data associated to the manifold. As such, it can be treated within the framework of simplicial databases and table manipulation of tiles in a simplicial database. For illustration, a set of three depictions, one for each of three different kinds of elementary operations on meshes, is shown in FIGS. 31, 32, and 33. In FIG. (31), the table (3103) corresponding to the mesh (3100) per the bidirectional arrow (3101) is restricted, per the projection (3104), to the table (3108) corresponding to the mesh (3106) per the arrow (3110). In FIG. 32), two meshes (3200) and (3202) are joined per arrow (3210) along an edge (3204), which is identified with an edge of each of meshes per the dashed arrows (3206) and (3208). The tables (3201) and (3203) corresponding to the meshes (3200) and (3202) are themselves along the identified simplices and the resulting table (3214) corresponds to the joined mesh mesh (3212). In FIG. 33), a union operation (3305) is applied to a mesh (3300) with corresponding table (3301) and a mesh (3302) with corresponding table (3303), producing per the arrow (3307) a mesh (3309) with corresponding table (3311).

By issuing commands via a user interface (UI) that may include a graphical display, haptic controllers such as a computer mouse or trackpad and keyboard, a user may construct a mesh by specifying subschema (subcomplexes of a mesh) using projections, ‘gluing’ simplices together, using joins, and taking the unions of data defined over different schema. In addition to these methods, and separately from the mesh schema, a user may also generate the mesh data directly, e.g. by direct input of audio or pressure data (e.g., using a pressure-sensitive device, or microphone), as described farther below.

More specifically, projection operation from a mesh to a sub-mesh is constructed simply by specifying a subschema of the mesh, and restricting the data of the mesh to the data of the subschema. This amounts to restricting the column space, of the table representing the entire mesh, to a subset of the columns. In comparison, a join is constructed as a categorical limit in the category of simplicial databases. More specifically, a join of two meshes at a simplex is constructed by taking the fiber product, or pullback, of a diagram specifying where the meshes are to be joined. Less abstractly, a join is constructed by first selecting a pair of connecting simplices, one in one mesh and one in the other, and then comparing the data over each for equality. Recall that a pullback is an object P in a diagram of shape

It can be defined in the case of sets and functions as

$$P = {\sum }_{a : A} {\sum }_{b : B} ( f ( a ) = g ( b ) ) .$$

In FIG. 32), a join of two meshes is shown. The join is taken at two connecting simplices, which are the edges shown in red. The joined mesh is the mesh with the two simplices identified, and where the data (e.g., the SPF) at each vertex of the connecting simplex in the new mesh is the data over the original simplices wherever they agreed (e.g., p₁(v₁)=p₂(v₂), where p₁ and p₂ are the SPFs of the first and second meshes, respectively, and 0 wherever they did not).

In contrast to a join, a union is constructed as a categorical colimit. Graphically, a union command can be issued by ‘dragging-and-dropping’ one mesh (schema) over another. This will result in the union of the rows of the tables of the two meshes. If there are rows in the tables corresponding to the different meshes which have the same row index, or key, then these ‘duplicate’ entries may be preserved in the union, or else conflated into one datum. In particular, the SPF of a mesh is always a function defined over the mesh at the current time, t=0. A table may also encode the data of one or many MFS over a mesh (i.e., buffers and the data in them are also encoded in the mesh); in this case, the table also contains rows which are indexed by times ‘t=1, t=2, t=3’, etc. Then entries with the same time indices may be conflated simply by adding the different functions defined at the same times.

### Automatic Mesh Generation

Lastly, meshes may be generated automatically. For example, a mesh may be generated from a ‘point cloud’ dataset, i.e. a set of points lying in some space. The locations of the points may correspond to the locations of sensors in the real world, e.g. to the locations of microphones or other devices for measuring acoustic pressure fluctuations. Or the points may lie in a ‘virtual space’ that is equipped with a metric.

Methods for mesh generation can be classified into two categories: methods which are generic, such as Delaunay triangulation-based methods; and more specialized surface reconstruction methods, which seek to reconstruct precisely an unknown surface hypothetically corresponding to the point-set. Methods of the former category are generally much simpler and more applicable, and we concentrate on them here. Specifically, in one method a mesh is constructed automatically from a dataset that is a set of points, and then the mesh is transformed to be Delauanay triangle via an edge-flipping algorithm. An analogous algorithm can be used to generate a tetrahedral mesh.

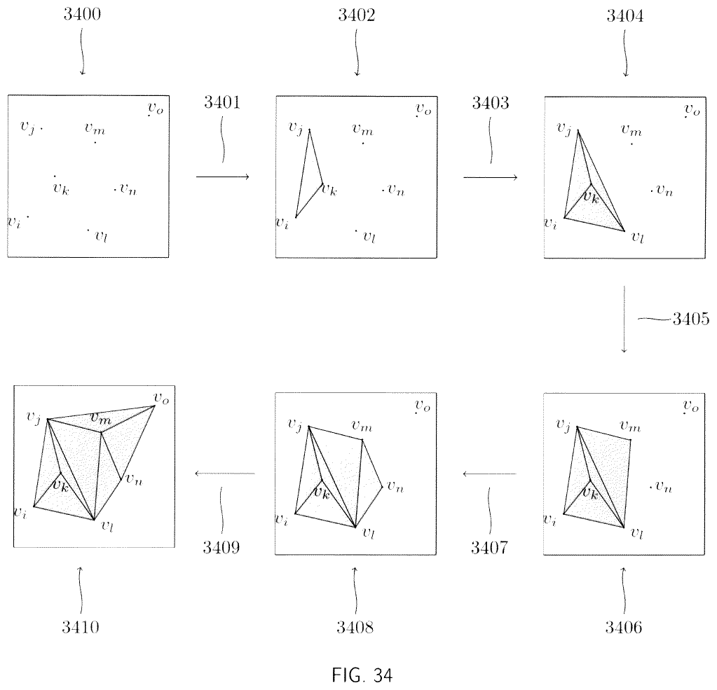

An incremental algorithm to produce a triangulation from a set of points in the plane is described in Chapter 3. of [S. L. Devadoss and J. O'Rourke, Discrete and Computational Geometry. Princeton University Press, 2011]], which we incorporate by reference. The sequence of steps taken in the algorithm is as follows. First, sort the points according to one dimension. Assuming that no sequence of three points in the given order are colinear, then the first three points determine a triangle. Now, consider the next point, p, in the ordered set of points and connect it with all previously considered points from the set that are visible to p (i.e., for a which a line segment exists that does not pass through any previously constructed triangle). Repeat this step for each next point in the ordered set of points, until all points have been connected. The result is a triangulation. If the input dataset of points is not in a planar space, the points can be projected onto a two-dimensional subspace and the planar triangulation algorithm can still be used. In FIG. 34), the incremental algorithm to produce a triangulation is depicted, wherein a point set (3400) is incrementally transformed to a triangulation (3410), via a sequence of maps (3401), (3403), (3405), (3407), and (3409).

The edge-flipping algorithm to produce a Delaunay triangulation from an arbitrary triangle mesh consists of the following simple step, which is then iterated: for each edge, e, of the triangulation T, if the sum of the angles opposite to it is greater than π, then flip the edge. This simple algorithm converges to a Delaunay triangulation after a finite number of steps. Since Delaunay triangulations are well-conditioned for numerical processing, this can be used to improve a mesh generated from the previously-described incremental algorithm, before evolving it as an OM.

### User Interface and User-Generated Input

The system of the present invention can be used, not only to propagate sound between participants as in a communication medium, or to simulate or implement sound propagation in an acoustic space, but also as a musical instrument by one or many users. This follows naturally as a use case from the general features of the system of the present invention. Specifically, a CP may include a sensor and/or an actuator that a user directly interacts with, in order to generate and/or hear sound processed by the system. In one example, the sensor may be a microphone, which the user may use to pick up speech or other sound. The sound received by the sensor may be transmitted as a MFS to an OM. For example, a sensor that is a single (point-like) microphone can be used to capture a MFS at a point (i.e., a trivial OM that is simply driven by any input forcing signal, and which does not evolve spatially since it has no spatial extent). In another example, there may be an OM in the shape of a sphere, which may receive sound streamed directly from a spherical array of microphones. A spatially extended OM, such as a spherical OM can also be used to act as a kind of ‘nexus’ to which one or many users are connected and able to stream sound directly to or from their respective physical locations and environments, or else by generating sounds in a digital environment and streaming digital signals generated there. For example, a band comprised of multiple musicians can stream the sounds, generated by a set of instruments played by the different musicians, on a OM. Conversely, sounds may be streamed from multiple OMs into a single physical space. In a particular example, one or many streams of sound may be sampled from the spherical OM and transmitted as MFS to users located in different physical environments and be played back in their respective environments.

In general, sensors (resp. actuators) in the real world may be arrays, i.e., may be comprised of many sensors (resp. actuators) that are distributed in space and whose positions in space may also be modeled using a mesh. Thus, sensor (resp. actuator) arrays can be used to directly sense (resp. actuate) MFS, if the sensors are modeled using a mesh. More specifically, a scalar field sensed over a sensor array that is modeled spatially as a simplicial manifold can be harmonically or conformally mapped to a an OM such that the field is reparameterized over the OM. Conversely, the a MFS parameterized over a simplicial submanifold of an OM can be harmonically or conformally mapped to an actuator array modeled spatially as a simplicial manifold, for application of a forcing signal into a physical environment.

Examples of sensor arrays include microphone arrays distributed approximately in the shape of a sphere, as e.g. are typically used in Ambisonics. A different kind of example is that of a pressure-sensitive surface, such as a touch-pad. A sensor of this latter type may be used as a musical instrument, whereby a user may directly generate a manual displacement signal on the sensor, i.e. by pressing up and down. This would allow a user to directly ‘draw’ a soundwave by generating a corresponding series of displacements; for example, if they pressed and released according to a sinusoidal displacement pattern, then a sinusoidal wave would be generated on the OM to which the pressure-sensitive pad were coupled. Similarly, if they generate multiple such displacement patterns, for example using two different fingers, then the result would be a ‘chord’, the different tones of which corresponded to the frequencies of the different displacement patterns (although the frequencies of these tones might be very low). More generally, a user could manually generate an arbitrary series of displacements, and this would directly generate a corresponding wave on the OM.

Non-pressure-based sensors and actuators may also be used. In particular, a device that senses or drives the electric or magnetic field strength or flux over a region of physical space or at a number of points can be used to sense or actuate a MFS. In a particular example of an application, a device that measures the pulse of a user may be used to generate a signal that is streamed to an OM. In another example, a brain-computer interface (BCI) may be used to sense neural oscillatory waves, such as alpha, beta, and gamma waves, using an EEG device consisting of one of many electrodes placed on the scalp or in proximity to the brain, and output the waves to an OM as a MFS.

### Visualization

OM meshes may be visualized, for example using a computer screen if the vertices are assigned positions in a Euclidean space of dimension less than or equal to three. Standard techniques from computer graphics can be used to modify the view taken of any given mesh; for example, meshes may be rotated using a click-and-drag user mechanic, may be zoomed in and out on, etc.

An important aspect of the visualization of OMs is that an OM may be visualized in two different modes: data view and structure view. In the first, the (SPF) data of the OM is visible, e.g. as the velocity field and by using a color-map. In the second, only the underlying simplicial manifold of the OM is visible, and the overlying data associated to the simplicial manifold is hidden from view. The former mode may be used as the default mode, and allow users to ‘visualize sound’ as it is propagating. In particular, the color at vertex v may be obtained via interpolation in a color space such as HSB or HSV. This can be done, specifically, by fixing a range of colors in the color-space, and then interpolating onto this range using the ratio |p(v)|/(heightₘₐₓ), where (heightₘₐₓ) is a maximum allowable displacement of the OM from zero-height, and where height is identified with the SPF value and the absolute value is used in order to have a symmetric color range about zero height.

The structure-view mode be used, for example, when editing meshes using the operations on tiles described above. When the structure-view mode is used to edit the mesh of an OM, automatic retriangulation of the OM may be turned off (so as to keep the structure of the mesh constant during editing).

### Movement of Coupling Interfaces

Coupling interfaces between OMs may be in motion over the respective OMs. For example, the location of a point-sensor can be moved along the surface of an OM, which might correspond to the motion of an audio source in an acoustic space. This can be achieved using the vector heat method. Specifically, given an input vector field X supported over a simplicial submanifold of an OM, a vector field parameterized over the entirety of the OM is produced. The steps taken in order to produce the output vector field are as follows. First, the vector heat flow

$$\frac{d}{d t} {Y}_{t} = {Δ}^{∇} {Y}_{t}$$

integrated for time t, with Y₀=X and where Δ^{∇} is the connection Laplacian; then, the scalar heat flow

$$\frac{d}{d t} {u}_{t} = Δ {u}_{t}$$

is integrated for time t, with u₀=|X|; next, the scalar heat flow

$$\frac{d}{d t} {ϕ}_{t} = {Δϕ}_{t}$$

is integrated for time t, with ϕ₀=1_{Ω}; and finally, the output vector field X̅ₜ=uₜYₜ/ϕₜ|Yₜ| is evaluated. See [N. Sharp, Y. Soliman, and K. Crane, “The Vector Heat Method,” ACM Trans. Graph., vol. 38, no. 3, pp. 1-19, 2019], which we incorporate by reference, for details such as the construction of the connection Laplacian.

### Componentry in a CPS

It should be noted that a CP may include a processor, a memory device, a communication interface, a peripheral device interface, a display device interface, and a storage device interface. It may also include a display device that may be coupled to or included within the CP. The memory device may be or include a device such as a Dynamic Random Access Memory (D-RAM), Static RAM (S-RAM), or other RAM or a flash memory. The storage device may be or include a hard disk, a magneto-optical medium, or another type of device for electronic data storage. The communication interface may be, for example, a communications port, a wired transceiver, a wireless transceiver, and/or a network card. The communication interface may be capable of communicating with a network using technologies such as Ethernet, fiber optics, microwave, Wireless Local Area Network (WLAN) technology, wireless cellular technology, and/or any other appropriate technology. The peripheral device interface may be an interface configured to communicate with one or more peripheral devices. The peripheral device interface may operate using a technology such as Universal Serial Bus (USB), Bluetooth, infrared, serial port, parallel port, and/or other appropriate technology. The peripheral device interface may, for example, receive input data from an input device such as a keyboard, a mouse, a trackball, a touch screen, a touch pad, a stylus pad, and/or other device. Alternatively or additionally, the peripheral device interface may communicate output data to a printer or other device that is attached to the CP via the peripheral device interface. The display device interface may be an interface configured to communicate data to the display device. The display device may be, for example, a monitor or television display, a plasma display, a liquid crystal display (LCD), organic light-emitting diodes (OLEDs), or Digital Light Processing (DLP). The display device interface may operate using technology such as Video Graphics Array (VGA), Digital Visual Interface (DVI), High-Definition Multimedia Interface (HDMI), or other appropriate technology. The display device interface may communicate display data from the processor to the display device for display by the display device.

An instance of a CP may be configured to perform any feature or combination of features described above. For example, a CP may be coupled to one or more sensors and/or one or more actuators described above through the peripheral device interface. The one or more sensors and/or one or more actuators may detect vibrations propagating in acoustic media. In such an instance, the memory device and/or the storage device may store instructions which, when executed by the processor, cause the processor to perform any feature or any combination of features described above. Alternatively or additionally, in such an instance, one or more of the features described above may be performed by the processor in conjunction with the memory device, communication interface, peripheral device interface, display device interface, and/or storage device. The CP may furthermore include multiples of each of the components listed above, and may be configured to perform, mutatis mutandis, analogous functionality to that described above.

A CPS may include a server that may be a conventional stand-alone web server, a server system, a computing cluster, or any combination thereof. The server may include a server rack, a data warehouse, network, or cloud type storage facility or mechanism that is in communication with the network. The server may include one or more central processing units (CPU), network interface units, input/output controllers, system memories, and storage devices. The CPU, network interface unit, input/output controller, system memory, and storage devices may be communicatively coupled via a bus. The system memory may include random access memory (RAM), read only memory (ROM), and one or more cache. The storage devices may include one or more applications, an operating system, and one or more databases. The one or more databases may include a database management system managed by Structure Query Language (SQL). The storage devices may take the form of, but are not limited to, a diskette, hard drive, CD-ROM, thumb drive, hard file, or a Redundant Array of Independent Disks (RAID). The server may be accessed by one or more CPs via the network using a mainframe, thin client, personal computer, mobile device, pad computer, or the like. Information processed by the CPU and/or operated upon or stored on the storage devices and/or in the system memory may be displayed to a client through a user device. The server may leverage a Service Oriented Architecture (SOA). For example, when a CP invokes a function, such as actuation in an acoustic medium, that function may be performed within the CP or it may be redirected to the server. This redirection may be performed by a service bus that exposes a set of service endpoints to CPs that interact with these services as if the services were local. The service bus may direct requests for those services to the appropriate service providers either locally or in the network based on configured mapping. Mapping may be done on a per service basis, allowing a mix of local and cloud-based service to be used. The service bus itself may be local or it may be located in the network. The disclosed system and methods may be designed for multi-tenancy, such that many entities may share the same physical database resources but may keep their respective data entirely private.

As used herein, the term “processor” broadly refers to and is not limited to a single- or multi-core processor, a special purpose processor, a conventional processor, a Graphics Processing Unit (GPU), a digital signal processor (DSP), a plurality of microprocessors, one or more micro-processors in association with a DSP core, a controller, a microcontroller, one or more Application Specific Integrated Circuits (ASICs), one or more Field Programmable Gate Array (FPGA) circuits, any other type of integrated circuit (IC), a system-on-a-chip (SOC), and/or a state machine.

As used herein, the term “computer-readable medium” broadly refers to an is not limited to a register, a cache memory, a ROM, a semiconductor memory device (such as a D-RAM, S-RAM, or other RAM), a magnetic medium such as a flash memory, a hard disk, a magneto-optical medium, an optical medium such as a CD-ROM, a DVDs, or BD, or other type of device for electronic data storage.

Although features and elements are described above in particular combinations, one of ordinary skill in the art will appreciate that each feature or element can be used alone or in any combination with the other features and elements. In addition, the methods described herein may be implemented in a computer program, software, or firmware incorporated in a computer-readable medium for execution by a computer or processor. Examples of computer-readable media include electronic signals (transmitted over wired or wireless connections) and computer-readable storage media include, but are limited to, a read only memory (ROM), a random access memory (RAM), a register, cache memory, semiconductor memory devices, magnetic media such as internal hard disks and removable disks, magneto-optical media, and optical media such as CD-ROM disks, and digital versatile disks (DVDs). A processor in association with software may be used to implement a radio frequency transceiver for use in any device or host computer.

What is claimed is:

1. A method for coupling Laplacian-driven field dynamics between a physical space and a cyber space of a field, said physical space and said cyber space adjoining at a coupling interface, comprising the steps of:
generating a first simplicial manifold having first vertices and a first discrete metric so as to represent a first geometry of said physical space;
generating a second simplicial manifold having second vertices and a second discrete metric so as to represent a second geometry of said cyber space;
determining a first simplicial submanifold of said first simplicial manifold representing said coupling interface and having a first set of coupling vertices, said first set of coupling vertices being a subset of said first vertices;
measuring physical forcing terms at said first set of coupling vertices in said first simplicial submanifold;
determining a second simplicial submanifold of said second simplicial manifold representing said coupling interface and having a second set of coupling vertices, said second set of coupling vertices being a subset of said second vertices;
determining a mapping from said first simplicial submanifold to said second simplicial submanifold;
applying said mapping to said physical forcing terms at said first set of coupling vertices to produce mapped cyber forcing terms at said second set of coupling vertices in said second simplicial submanifold; and
producing a time step of said field over said cyber space by application of a time step operator for said Laplacian-driven field dynamics to second vertices of said second manifold, where said time step operator incorporates said mapped cyber forcing terms;
applying an inverse of said mapping to cyber forcing terms at said second set of coupling vertices to produce mapped physical forcing terms at said first set of coupling vertices in said first simplicial submanifold; and
transducing said values of said mapped physical forcing terms into physical dynamics at said first set of coupling vertices.

2. The method of claim 1 wherein upon application of said time step said second manifold has an absorbing boundary condition.

3. The method of claim 2 where said absorbing boundary condition is implemented by setting a first time derivative of said field at each vertex on a boundary equal to a first inwards-facing normal derivative of said field at each said vertex on said boundary.

4. The method of claim 1 wherein said Laplacian-driven field dynamics is a heat equation and said field is heat.

5. The method of claim 1 wherein said Laplacian-driven field dynamics is an inhomogeneous wave equation.

6. The method of claim 5 wherein said inhomogeneous wave equation in a continuous space is of the form
$$\frac{{d}^{2} u}{d {t}^{2}} = L u + f ,$$
where u is said field, ƒ is said mapped physical forcing term and said mapped cyber forcing term, and Δ is the Laplacian, which in Cartesian coordinates is given by
$$\frac{{\partial }^{2}}{\partial {x}^{2}} + \frac{{\partial }^{2}}{\partial {y}^{2}} + \frac{{\partial }^{2}}{\partial {z}^{2}} .$$

7. The method of claim 6 wherein said inhomogeneous wave equation is an electromagnetic fields equation and said field is electric and magnetic fields.

8. The method of claim 6 wherein said inhomogeneous wave equation is an acoustics equation and said field is pressure.

9. The method of claim 8 wherein said measuring of one of said physical forcing terms is performed by a pressure sensor.

10. The method of claim 8 wherein said measuring of one of said physical forcing terms is performed by a microphone.

11. The method of claim 1 wherein said time step operator for said Laplacian-driven field dynamics is the discrete Laplace-Beltrami operator.

12. The method of claim 1 wherein weight factors w ij for said discrete Laplace-Beltrami operator are given by
$${w}_{i j} = \frac{1}{n ( n - 1 )} {\sum }_{i j ∈ σ} {V}_{{\overline{σ}}_{i j}} cot {θ}_{{\overline{σ}}_{i j}}$$
where the summation is over all n-simplices σ containing edge eᵢⱼ, σ̅ᵢⱼ is the (n−2)-simplex obtained by removing vertices vᵢ and vⱼ from σ, V_{σ̅}_{ᵢⱼ} is the volume of σ̅ᵢⱼ, and θ_{σ̅}_{ᵢⱼ} is the internal dihedral angle at σ̅ᵢⱼ.

13. The method of claim 1 wherein said physical space and said cyber space are three dimensional, and the discrete Laplace-Beltrami operator L has entries
$${L}_{i j} = - {w}_{i j} , {L}_{i i} = - {\sum }_{i j} {L}_{i j} , where {w}_{i j} = \frac{1}{6} {\sum }_{i j k l} {l}_{k l} cot {θ}_{k l}^{i j} ,$$
where the sum is taken over all tetrahedra containing edge eᵢⱼ and θₖₗ^{ij} is the interior dihedral angle at eᵢⱼ of the tetrahedron with vertices vᵢ, vⱼ, vₖ, and vₗ.

14. The method of claim 1 wherein simplices of said first simplicial manifold and said second simplicial manifold are triangular simplices, and said time step operator at vertex vᵢ is
$${( L u )}_{i} = {\sum }_{i j} ( cot {α}_{i j} + cot {β}_{i j} ) ( {u}_{j} - {u}_{i} )$$
where u i is said field at vertex v i, u j is said field at vertex v j, (L u) i is the time step operator at vertex v i, the summation is over all said vertices v j connected by an edge e ij to said vertex v i, and angles αᵢⱼ and βᵢⱼ are interior angles of said triangular simplices opposite said edge e ij.

15. The method of claim 12 wherein said Laplacian-driven field dynamics on said first simplicial manifold and said second simplicial manifold is of the form
$$\frac{{d}^{2} u}{d {t}^{2}} = L u + G f ,$$
where u is said field, f is said mapped physical forcing term and said mapped cyber forcing term, and G is a mass matrix which weights contributions to a value of f at a vertex v i by the area of simplices including said vertex vᵢ.

16. The method of claim 1 wherein said mapping is a conformal mapping.

17. The method of claim 16 wherein said mapping from said first simplicial submanifold to said second simplicial submanifold includes a first intermediate mapping from said first simplicial submanifold to an intermediate simplicial manifold and a second intermediate mapping from said intermediate simplicial manifold to said second simplicial submanifold.

18. The method of claim 17 wherein said intermediate simplicial manifold is a topological disk.

19. The method of claim 17 wherein said intermediate simplicial manifold is a disk.

20. The method of claim 16 wherein said forcing terms f on said first set of coupling vertices are converted to complex values ƒ̅=a+bi, where real components a are values of forcing terms on said first set of coupling vertices and imaginary components b satisfy the Cauchy-Riemann equation.

21. The method of claim 1 wherein a refinement in locations of said second vertices in said second simplicial manifold is made on the basis of the Dirichlet energy of said second vertices.

22. The method of claim 1 wherein a refinement in locations of said second vertices in said second simplicial manifold is made on the basis of a gradient in said field at said second vertices.

23. The method of claim 22 wherein said refinement in said locations of said second vertices in said second simplicial manifold is made on the basis of differences in said gradient in said field across edges.

24. The method of claim 23 wherein said second vertices define a two-dimensional space and said refinement in said locations of said second vertices in said second simplicial manifold is made on the basis of edge lengths at said second vertices.

25. The method of claim 24 wherein said refinement in said locations of said second vertices in said second simplicial manifold is made on the basis of an estimator η where
$$η = {\sum }_{T} {\sum }_{i j} {( {l}_{i j} )}^{2} \cdot \vert {[ ∇ û ]}_{i j} {\vert}^{2} ,$$
where the first sum is over all triangles T in said first simplicial manifold, the second sum is over edges e ij within each triangle T, 1 ij is the length of edge e ij, and [∇u]ᵢⱼ is a difference in the gradient of said field u between the two of said triangles T sharing said edge e ij.

26. The method of claim 23 wherein said second vertices define a three-dimensional space and said refinement in said locations of said second vertices in said second simplicial manifold is made on the basis of areas of faces of simplices of said second vertices.

27. The method of claim 26 wherein said refinement in said locations of said second vertices in said second simplicial manifold is made on the basis of an estimator η where
$$η = {\sum }_{Γ} {\sum }_{i j k} {( {A}_{i j k} )}^{2} \cdot \vert {[ ∇ û ]}_{{i}_{J} k} {\vert}^{2} ,$$
where the first sum is over all tetrahedra F in said first simplicial manifold, the second sum is over all triangular faces ijk within each tetrahedron Γ, and [∇u]ᵢⱼₖ is a difference in the gradient of said field u across face ijk of tetrahedra sharing said face ijk.

28. A method for coupling Laplacian-driven field dynamics between a physical space and a cyber space of a field, said physical space and said cyber space adjoining at a coupling interface, comprising the steps of:
generating a first simplicial manifold having first vertices and a first discrete metric so as to represent a first geometry of said physical space;
generating a second simplicial manifold having second vertices and a second discrete metric so as to represent a second geometry of said cyber space;
determining a first simplicial submanifold of said first simplicial manifold representing said coupling interface and having a first set of coupling vertices, said first set of coupling vertices being a subset of said first vertices;
determining a second simplicial submanifold of said second simplicial manifold representing said coupling interface and having a second set of coupling vertices, said second set of coupling vertices being a subset of said second vertices;
determining a mapping from said first simplicial submanifold to said second simplicial submanifold;
applying an inverse of said mapping to cyber forcing terms at said second set of coupling vertices to produce mapped physical forcing terms at said first set of coupling vertices in said first simplicial submanifold; and
transducing said values of said mapped physical forcing terms into physical dynamics at said first set of coupling vertices.

29. The method of claim 28 further including the steps of
applying said mapping to physical forcing terms at said first set of coupling vertices to produce mapped cyber forcing terms at said second set of coupling vertices in said second simplicial submanifold;
producing a time step of said field over said cyber space by application of a time step operator for said Laplacian-driven field dynamics to second vertices of said second manifold, where said time step operator incorporates said mapped cyber forcing terms, thereby producing a time-stepped field;
again applying an inverse of said mapping to time-stepped cyber forcing terms at said second set of coupling vertices to produce time-stepped mapped physical forcing terms at said first set of coupling vertices in said first simplicial submanifold; and
transducing said values of said time-stepped mapped physical forcing terms into physical dynamics at said first set of coupling vertices.
